(19) United States
(12) Patent Application Publication
(10) Pub. No.: US 2025/0344536 A1
(43) Pub. Date: Nov. 6, 2025

(54) IMAGE SENSOR

(71) Applicant: SAMSUNG ELECTRONICS CO., LTD., Suwon-si (KR)

(72) Inventors: SEUNGJOON LEE, Suwon-si (KR); Jaesang Yoo, Suwon-si (KR); Jeongki Kim, Suwon-si (KR); Chungho Song, Suwon-si (KR); Minwook Jung, Suwon-si (KR)

(73) Assignee: SAMSUNG ELECTRONICS CO., LTD., Suwon-si (KR)

(21) Appl. No.: 19/008,187

(22) Filed: Jan. 2, 2025

(30) Foreign Application Priority Data
May 3, 2024 (KR) 10-2024-0059260

(51) Int. Cl. H10F 39/00; H04N 25/633

(52) U.S. Cl. CPC H10F 39/807; H04N 25/633; H10F 39/811

(57) ABSTRACT

The disclosure relates to an image sensor including a substrate having a pixel area and a peripheral area, a plurality of photoelectric converters provided inside the substrate corresponding to the plurality of pixels, a pixel isolation pattern provided between the plurality of photoelectric converters, a dummy isolation pattern provided inside the substrate in the peripheral area, and a dummy isolation contact provided on a first surface of the substrate in the peripheral area and connected to the dummy isolation pattern. The dummy isolation pattern has a width different from a width of the pixel isolation pattern. A first portion of the dummy isolation contact is provided inside the substrate, and a width of the dummy isolation contact is greater than or substantially equal to the width of the dummy isolation pattern.

### CROSS-REFERENCE TO RELATED APPLICATION

This application is based on and claims priority to and the benefit of Korean Patent Application No. 10-2024-0059260 filed in the Korean Intellectual Property Office on May 3, 2024, the entire contents of which are incorporated herein by reference.

### BACKGROUND

### 1. Field

The disclosure relates to an image sensor.

### 2. Description of Related Art

In imaging technology, image sensors may include a complementary metal-oxide semiconductor (CMOS) image sensor or a charge coupled device (CCD) sensor. CMOS image sensors are solid-state image sensing devices using complementary metal-oxide semiconductors (CMOSs). As compared to CCD image sensors with high-voltage analog circuits, CMOS image sensors have the advantages of low manufacturing costs and low power consumption due to the small sizes of elements, so CMOS image sensors are mainly mounted in home appliances including portable devices such as smart phones, digital cameras, etc.

A pixel array constituting a CMOS image sensor includes a photodiode in each pixel. The photodiodes may generate electrical signals that vary depending on the amounts of incident light, and the CMOS image sensor may synthesize an image by processing the electrical signals.

Recently, in view of the demand for high-definition images, pixels that constitute CMOS image sensors are being required to be downsized. As this demand for downsizing increases, it is critical to effectively reduce occurrence of dark current and white spots.

### SUMMARY

The disclosure attempts to provide an image sensor with improved reliability and productivity.

According to one or more example embodiments, it is possible to reduce occurrence of dark current by applying a voltage to the dummy isolation pattern by the dummy isolation contacts, in the peripheral area provided outside the pixel area.

Also, a manufacturing process can be simplified by forming the dummy isolation contacts together in an operation of forming the transfer gates and the like that are provided in the pixel area.

### BRIEF DESCRIPTION OF DRAWINGS

FIG. 1 is a block diagram of an image sensor according to one or more example embodiments.

FIG. 2 is a circuit diagram of an active pixel array of the image sensor according to one or more example embodiments.

FIG. 3 is a plan view of the image sensor according to one or more example embodiments.

FIG. 4 is a plan view illustrating a pixel area of the image sensor according to one or more example embodiments.

FIG. 5 is an enlarged view of part P1 of FIG. 3 according to one or more example embodiments.

FIG. 6 is a cross-sectional view taken along line I-I′ of FIG. 5 according to one or more example embodiments.

FIG. 7 is an enlarged view of part P2 of FIG. 6 according to one or more example embodiments.

FIG. 8 is a plan view illustrating a pixel area of an image sensor according to one or more example embodiments.

FIGS. 9 to 12 are plan views illustrating contact regions of image sensors according to one or more example embodiments.

FIGS. 13 to 24 are cross-sectional views sequentially illustrating a method of manufacturing the image sensor according to one or more example embodiments.

### DETAILED DESCRIPTION

In the following detailed description, only certain embodiments have been shown and described, simply by way of illustration. The present invention can be variously implemented and is not limited to the following embodiments.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present invention is not limited thereto. In the drawings, the thickness of layers, films, panels, regions, etc., are exaggerated for clarity. In the drawings, for understanding and ease of description, the thickness of some layers and areas is exaggerated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

Further, throughout this specification, when it is referred to as “on a plane”, it means when a target part is viewed from above, and when it is referred to as “on a cross-section”, it means when the cross-section obtained by cutting a target part vertically is viewed from the side.

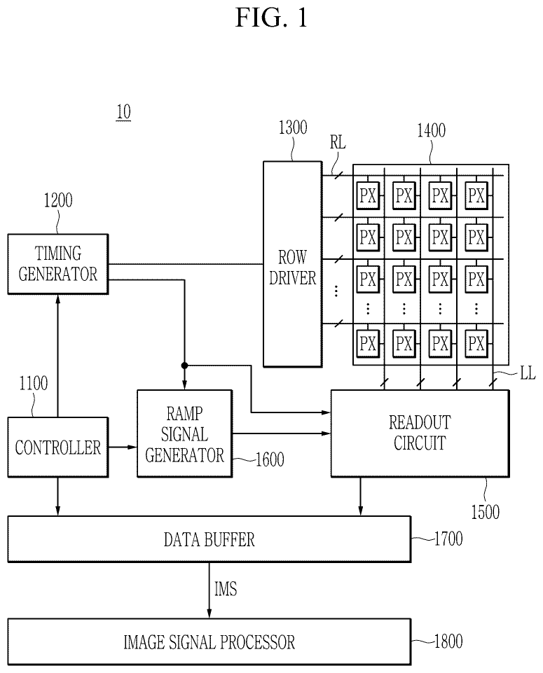

Hereinafter, an image sensor according to an embodiment will be described with reference to FIGS. 1 to 7.

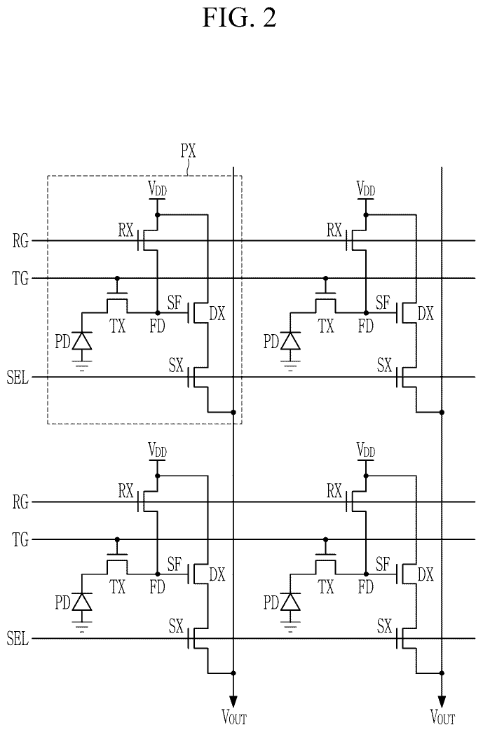

FIG. 1 is a block diagram of an image sensor according to one or more example embodiments. FIG. 2 is a circuit diagram of an active pixel array of the image sensor according to one or more example embodiments.

Referring to FIGS. 1 and 2, an image sensor 10 according to an embodiment may include a controller 1100, a timing generator 1200, a row driver 1300, an active pixel array 1400, a readout circuit 1500, a ramp signal generator 1600, a data buffer 1700, and an image signal processor 1800.

According to an embodiment, the image signal processor 1800 may be provided outside the image sensor 10.

The image sensor 10 may generate an image signal by converting light received from the outside into an electrical signal. The image signal (IMS) may be provided to the image signal processor 1800.

The image sensor 10 may be provided in an electronic device having an image or light sensing function, The image sensor 10 may be mounted in an electronic device having an image or light sensing function. For example, the image sensor 10 may be provided in electronic devices such as cameras, smart phones, wearable devices, IoT (Internet of Things) devices, home appliances, tablet PCs (personal computers), personal digital assistants (PDAs), portable multimedia players (PMPs) navigation devices, drones, advanced drivers assistance systems (ADASs), etc. Also, the image sensor 10 may be mounted in electronic devices which are incorporated as components in vehicles, furniture, manufacturing equipment, doors, various measuring devices, etc.

The controller 1100 may generally control the individual constituent elements 1200, 1300, 1500, 1600, and 1700 included in the image sensor 10.

The controller 1100 may control the operation timings of the individual constituent elements 1200, 1300, 1500, 1600, and 1700, using control signals.

According to an embodiment, the controller 1100 may receive a mode signal indicating an imaging mode, from an application processor, and generally control the image sensor 10 on the basis of the received mode signal. For example, the application processor may determine an imaging mode of the image sensor 10 according to various scenarios such as the illumination in the imaging environment, the user's resolution setting, a sensed or learned state, etc., and provide the determined result as a mode signal to the controller 1100.

The controller 1100 may perform control such that a plurality of active pixels PX of the active pixel array 1400 outputs pixel signals according to the imaging mode, and the active pixel array 1400 may output the pixel signals of the plurality of individual active pixels PX or the pixel signals of some of the plurality of active pixels PX, and the readout circuit 1500 may sample and process the pixel signals received from the active pixel array 1400.

The timing generator 1200 may generate a signal which is a reference for the operation timings of the components of the image sensor 10. The timing generator 1200 may control timings of the row driver 1300, the readout circuit 1500, and the ramp signal generator 1600. The timing generator 1200 may provide a control signal to control the timings of the row driver 1300, the readout circuit 1500, and the ramp signal generator 1600.

The active pixel array 1400 may include the plurality of active pixels PX, and a plurality of row lines RL and a plurality of column lines LL that are coupled to the plurality of active pixels PX, respectively.

The plurality of active pixels PX included in the active pixel array 1400 may be arranged in a matrix. Each of the active pixels PX may include a transfer transistor TX. Each active pixel PX may further include logic transistors RX, SX, and DX.

The logic transistors may be a reset transistor RX, a selection transistor SX, or a source follower transistor DX. The transfer transistor TX may include a transfer gate TG. Each active pixel PX may further include a photoelectric converter PD and a floating diffusion zone FD. The logic transistors RX, SX, and DX may be shared by a plurality of active pixels PX.

The photoelectric converter PD may sense incident light from the outside, and convert the incident light into electrical signals according to the amounts of light, i.e., into a plurality of analog pixel signals. The photoelectric converter PD may include a photodiode, a photo transistor, a photogate, a pinned photodiode, or a combination thereof.

Also, the photoelectric converter PD may be a single-photon avalanche diode (SPAD) which is applied to a 3D sensor pixel. The levels of analog pixel signals which are output from the photoelectric converter PD may be proportional to the amounts of charge which are output from the photoelectric converter PD. For example, the levels of analog pixel signals which are output from the photoelectric converter PD may be determined depending on the amount of light which enters the active pixel array 1400.

The transfer transistor TX may transfer charge generated by the photoelectric converter PD, to the floating diffusion zone FD. The floating diffusion zone FD may receive and accumulate the charge generated by the photoelectric converter PD. Depending on the amount of photoelectric charge accumulated in the floating diffusion zone FD, the source follower transistor DX may be controlled.

The reset transistor RX may periodically reset the charge accumulated in the floating diffusion zone FD. The drain electrode of the reset transistor RX may be connected to the floating diffusion zone FD and the source electrode thereof be connected to a power voltage V_{DD}. In an example case in which the reset transistor RX is turned on, the power voltage V_{DD} connected to the source electrode of the reset transistor RX may be applied to the floating diffusion zone FD. Therefore, when the reset transistor RX is turned on, the charge accumulated in the floating diffusion zone FD may be released, whereby the floating diffusion zone FD may be reset.

The source follower transistor DX including a source follower gate electrode SF may serve as a source follower buffer amplifier. The source follower transistor DX may amplify a potential change in the floating diffusion zone FD, and output the result to an output line Vout.

The selection transistor SX including a selection gate electrode SEL may select active pixels PX to be read out, on a row-by-row basis. In an example case in which the selection transistor SX is turned on, the power voltage V_{DD} may be applied to the drain electrode of the source follower transistor DX.

The plurality of row lines RL may extend in a first direction, and be connected to active pixels PX arranged along the first direction. For example, a control signal that is output from the row driver 1300 to a row line RL may be transferred to the gates of transistors of a plurality of active pixels PX connected to the corresponding row line RL.

Each column line LL may extend in a second direction intersecting the first direction, and be connected to a plurality of active pixels PX arranged along the second direction. A plurality of pixel signals that is output from the plurality of active pixels PX may be transferred to the readout circuit 1500 through the plurality of column lines LL.

On the active pixel array 1400, a color filter layer and a micro lens layer may be provided. The micro lens layer may include a plurality of micro lenses, and at least one active pixel PX corresponding to each of the plurality of micro lenses may be provided.

The color filter layer may include color filters of red, green, blue, etc. For example, with respect to one active pixel PX, a color filter of one color may be provided between the active pixel PX and a micro lens corresponding thereto.

The row driver 1300 may generate a control signal for driving the active pixel array 1400, in response to a control signal from the timing generator 1200, and provide the control signal to the plurality of active pixels PX of the active pixel array 1400 through the plurality of row lines RL.

According to an embodiment, the row driver 1300 may control the active pixels PX in row line units, such that the active pixels sense incident light. Each row line unit may include at least one row line RL. For example, the row driver 1300 may provide a transfer signal, a reset signal, a selection signal, and the like to the active pixel array 1400.

The readout circuit 1500 may convert pixel signals (or electrical signals) received from active pixels PX coupled to a selected row line RL among the plurality of active pixels PX, into pixel values indicating the amounts of light, in response to a control signal from the timing generator 1200. The readout circuit 1500 may convert pixel signals output through corresponding column lines LL into pixel values. For example, the readout circuit 1500 may convert pixel signals into pixel values by comparing the pixel signals with ramp signals. Pixel values may be image data items, each of which has a plurality of bits. For example, the readout circuit 1500 may include a selector, a plurality of comparators, a plurality of counter circuits, etc.

The ramp signal generator 1600 may generate a reference signal and transmit the reference signal to the readout circuit 1500.

The ramp signal generator 1600 may include current sources, resistors, and capacitors. The ramp signal generator 1600 may adjust ramp voltage which is voltage to be applied to a ramp resistor by adjusting the current magnitude of a variable current source or the resistance value of a variable resistor. In this way, the ramp signal generator may generate a plurality of ramp signals which falls or rise at slopes determined depending on the current magnitudes of variable current sources or the resistance values of variable resistors.

The data buffer 1700 may store the pixel values of the plurality of active pixels PX coupled to the selected column line LL, received from the readout circuit 1500, and output the stored pixel values in response to an enable signal from the controller 1100.

The image signal processor 1800 may perform image signal processing on image signals received from the data buffer 1700. For example, the image signal processor 1800 may receive a plurality of image signals from the data buffer 1700, and synthesize the received image signals to generate one image.

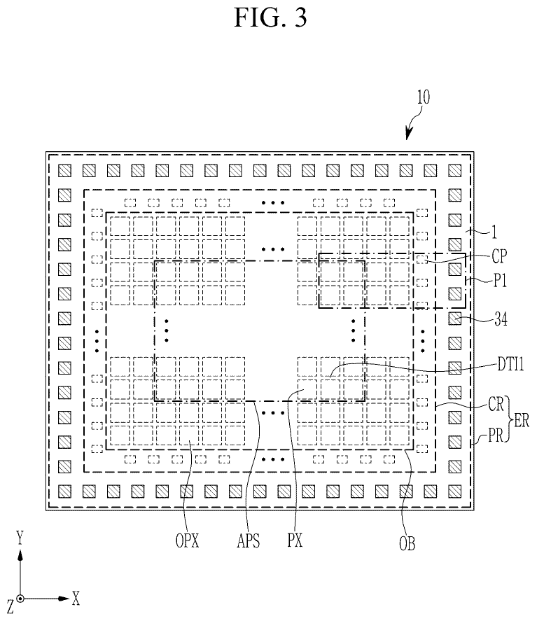

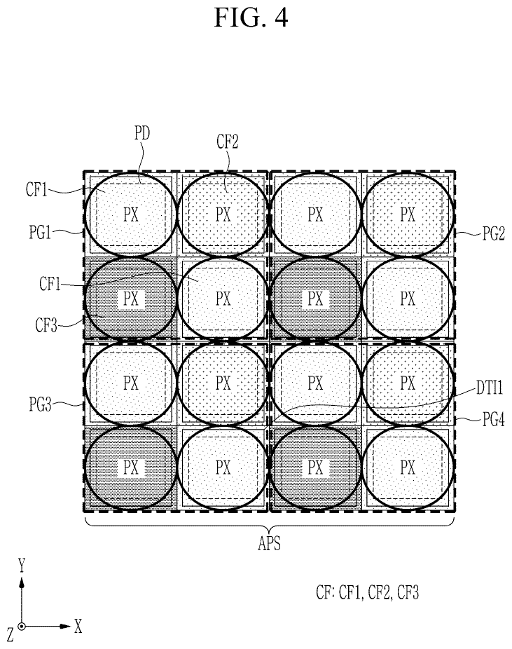

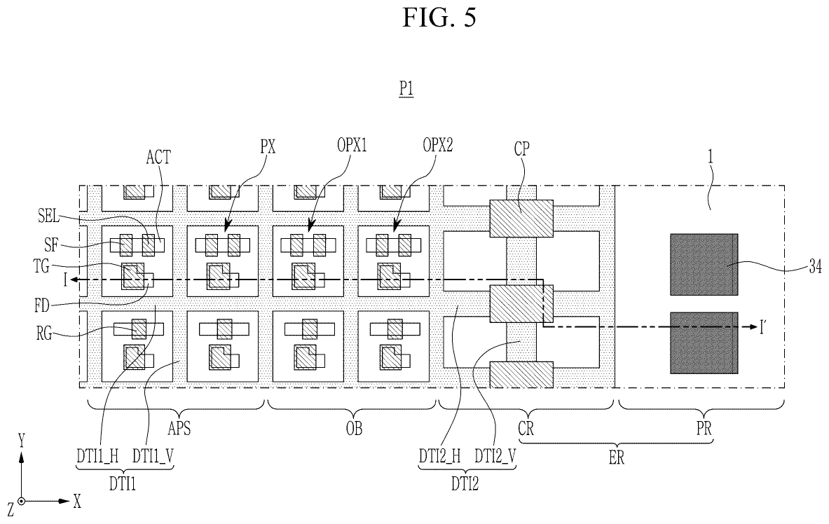

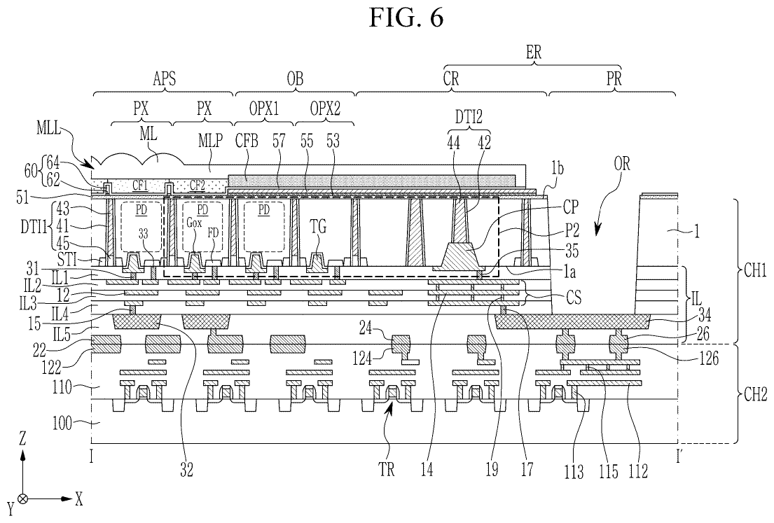

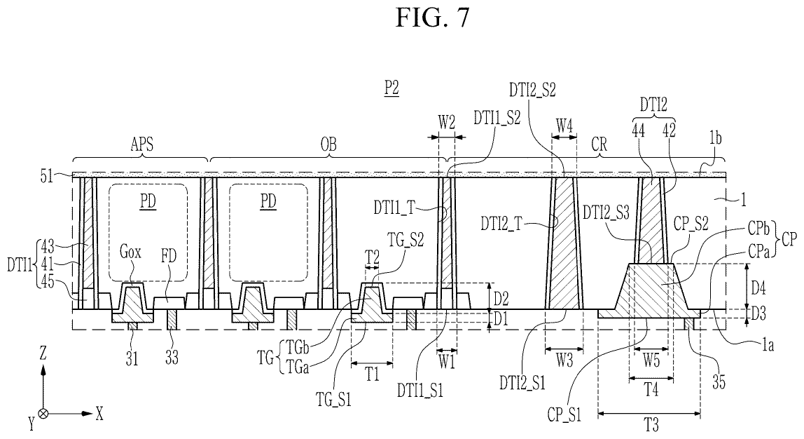

FIG. 3 is a plan view of the image sensor according to one or more example embodiments. FIG. 4 is a partial plan view of the image sensor according to one or more example embodiments. FIG. 5 is an enlarged view of part P1 of FIG. 3. FIG. 6 is a cross-sectional view taken along line I-I′ of FIG. 5. FIG. 7 is an enlarged view of part P2 of FIG. 6.

Referring to FIGS. 3 to 7, the image sensor 10 according to one or more example embodiments may have a structure in which a first chip CH1 and a second chip CH2 are bonded. For example, the first chip CH1 may be provided on the second chip CH2.

The first chip CH1 may perform an image sensing function. The second chip CH2 may include circuits for driving the first chip CH1 or for processing and storing electrical signals generated by the first chip CH1.

The first chip CH1 may include a first substrate 1, a pixel isolation pattern DTI1, a dummy isolation pattern DTI2, an element isolation pattern STI, a plurality of photoelectric converters PD, a plurality of floating diffusion zones FD, a plurality of transfer gates TG, a plurality of dummy isolation contacts CP, a color filter CF, and a micro lens layer MLL.

For example, the first substrate 1 may include a pixel area APS, an optical black area OB, and a peripheral area ER.

The first substrate 1 may include a front surface 1a and a rear surface 1b facing each other. Hereinafter, the front surface 1a and the rear surface 1b will be referred to as the first surface 1a and the second surface 1b, respectively. The second surface 1b of the substrate 1 may be a light receiving surface which light enters.

The optical black area OB and peripheral area ER of the first substrate 1 may be provided on at least one side of the pixel area APS. For example, the optical black area OB and the peripheral area ER may be sequentially provided on the outside of the pixel area APS, and the optical black area OB may surround the pixel area APS. For example, the optical black area OB may be provided between the pixel area APS and the peripheral area ER.

The peripheral area ER may include a contact region CR and a pad region PR. For example, the contact region CR and the pad region PR may be sequentially provided on the outside of the optical black area OB, and the contact region CR may surround the optical black area OB, and the pad region PR may surround the contact region CR. For example, the contact region CR may be provided between the optical black area OB and the pad region PR. However, this is an example, and the arrangement relationship of the optical black area OB, the contact region CR, and the pad region PR may be variously changed.

The first substrate 1 may be, for example, a silicon single crystal wafer, a silicon epitaxial layer, or a silicon on insulator (SOI) substrate. The first substrate 1 may be doped with an impurity of a first conductivity type. For example, the impurity of the first conductivity type may be a p-type impurity. For example, the p-type impurity may include, but is not limited to, aluminum (Al), boron (B), indium (In), and/or gallium (Ga).

Each of the pixel isolation pattern DTI1 and the dummy isolation pattern DTI2 may be provided inside the first substrate 1. The pixel isolation pattern DTI1 and the dummy isolation pattern DTI2 may be provided inside a first isolation trench DTI1_T and a second isolation trench DTI2_T passing through the first substrate 1, respectively. The pixel isolation pattern DTI1 and the dummy isolation pattern DTI2 may be frontside deep trench isolation (FDTI).

The pixel isolation pattern DTI1 may include a first surface DTI1_S1 and a second surface DTI1_S2 facing each other, and the dummy isolation pattern DTI2 may include a first surface DTI2_S1 and a second surface DTI2_S2 facing each other.

According to an embodiment, each of the pixel isolation pattern DTI1 and the dummy isolation pattern DTI2 may pass through the first substrate 1. For example, the first surface DTI1_S1 of the pixel isolation pattern DTI1 and the first surface DTI2_S1 of the dummy isolation pattern DTI2 may be in contact with the first surface 1a of the first substrate 1, and the second surface DTI1_S2 of the pixel isolation pattern DTI1 and the second surface DTI2_S2 of the dummy isolation pattern DTI2 may be in contact with the second surface 1b of the first substrate 1.

In some embodiments, the pixel isolation pattern DTI1 and the dummy isolation pattern DTI2 may be provided inside the first isolation trench DTI1_T and the second isolation trench DTI2_T. The first isolation trench DTI1_T and the second isolation trench DTI2_T may be formed by recessing some portions of the first substrate 1, respectively. For example, the first surface DTI1_S1 of the pixel isolation pattern DTI1 and the first surface DTI2_S1 of the dummy isolation pattern DTI2 may be provided so as to be in contact with the first surface 1a of the first substrate 1 and the second surface DTI1_S2 of the pixel isolation pattern DTI1 and the second surface DTI2_S2 of the dummy isolation pattern DTI2 may be provided so as to be spaced apart from the second surface 1b of the first substrate 1.

In an example case in which the second surface DTI1_S2 of the pixel isolation pattern DTI1 and the second surface DTI2_S2 of the dummy isolation pattern DTI2 are spaced apart from the second surface 1b of the first substrate 1 as described above, the second surface DTI1_S2 of the pixel isolation pattern DTI1 and the second surface DTI2_S2 of the dummy isolation pattern DTI2 may have a rounded shape.

In some embodiments, the pixel isolation pattern DTI1 may further include a channel stop region. For example, the pixel isolation pattern DTI1 may further include a channel stop region provided between the second surface 1b of the first substrate 1 and the second surface DTI1_S2 of the pixel isolation pattern DTI1.

The channel stop region may be doped into a conductivity type different from that of the photoelectric converter PD. For example, the photoelectric converter PD may be doped with an n-type impurity, and the channel stop region may be doped with a p-type impurity.

According to an example embodiment illustrated in FIGS. 6 and 7, the second surface DTI1_S2 of the pixel isolation pattern DTI1, the second surface DTI2_S2 of the dummy isolation pattern DTI2, and the second surface 1b of the first substrate 1 are flat. However, the disclosure is not limited thereto, and as such, according to another embodiment, the second surface DTI1_S2 of the pixel isolation pattern DTI1, the second surface DTI2_S2 of the dummy isolation pattern DTI2, and the second surface 1b of the first substrate 1 may have curvatures or may be curved.

According to an embodiment, a width of each of the pixel isolation pattern DTI1 and the dummy isolation pattern DTI2 decreases in a direction from the first surface 1a of the first substrate 1 toward the second surface 1b. For example, each of the pixel isolation pattern DTI1 and the dummy isolation pattern DTI2 may have an inclined side surface.

The width W1 of the first surface DTI1_S1 of the pixel isolation pattern DTI1 may be greater than the width W2 of the second surface DTI1_S2. For example, the pixel isolation pattern DTI1 may have the maximum width at the first surface DTI1_S1 and have the minimum width at the second surface DTI1_S2.

Also, the width W3 of the first surface DTI2_S1 of the dummy isolation pattern DTI2 may be greater than the width W4 of the second surface DTI2_S2. For example, the dummy isolation pattern DTI2 may have a maximum width at the first surface DTI2_S1 and have a minimum width at the second surface DTI2_S2.

According to an embodiment, the width of the dummy isolation pattern DTI2 may be greater than the width of the pixel isolation pattern DTI1. For example, as the width of the second isolation trench DTI2_T where the dummy isolation pattern DTI2 is provided is greater than the width of the first isolation trench DTI1_T where the pixel isolation pattern DTI1 is provided, the widths of the pixel isolation pattern DTI1 and the dummy isolation pattern DTI2, which are provided inside the first isolation trench DTI1_T and the second isolation trench DTI2_T, respectively, may become different from each other.

For example, the width W3 of the first surface DTI2_S1 of the dummy isolation pattern DTI2 may be greater than the width W1 of the first surface DTI1_S1 of the pixel isolation pattern DTI1, and the width W4 of the second surface DTI2_S2 of the dummy isolation pattern DTI2 may be greater than the width W2 of the second surface DTI1_S2 of the pixel isolation pattern DTI1. For example, the maximum width of the dummy isolation pattern DTI2 may be greater than the maximum width of the pixel isolation pattern DTI1, and the minimum width of the dummy isolation pattern DTI2 may be greater than the minimum width of the pixel isolation pattern DTI1.

Since the width of each of the pixel isolation pattern DTI1 and the dummy isolation pattern DTI2 decreases in a cross-sectional view as described above, in an example case in which a maximum width of the dummy isolation pattern DTI2 is greater than a maximum width of the pixel isolation pattern DTI1, the minimum width of the dummy isolation pattern DTI2 may be greater than the minimum width of the pixel isolation pattern DTI1.

According to an embodiment, the maximum width of the dummy isolation pattern DTI2 may be equal to or smaller than about two times the maximum width of the pixel isolation pattern DTI1. For example, the width W3 of the first surface DTI2_S1 of the dummy isolation pattern DTI2 may be equal to or smaller than about two times the width W1 of the first surface DTI1_S1 of the pixel isolation pattern DTI1. For example, the maximum width of the dummy isolation pattern DTI2 may be about 1.5 times to about two times the maximum width of the pixel isolation pattern DTI1. However, this is an example, and the difference between the maximum width of the dummy isolation pattern DTI2 and the maximum width of the pixel isolation pattern DTI1 is not limited to the above-mentioned range, and may be variously changed.

Further, since the width of each of the pixel isolation pattern DTI1 and the dummy isolation pattern DTI2 decreases in a cross-sectional view as described above, the above-mentioned numerical range related to the relationship between the maximum width of the pixel isolation pattern DTI1 and the maximum width of the dummy isolation pattern DTI2 may be applied substantially equally to the relationship between the minimum width of the pixel isolation pattern DTI1 and the minimum width of the dummy isolation pattern DTI2.

The pixel isolation pattern DTI1 may include a first insulating isolation pattern 41, a first conductive isolation pattern 43, and an isolation capping pattern 45, and the dummy isolation pattern DTI2 may include a second insulating isolation pattern 42 and a second conductive isolation pattern 44.

For example, the first insulating isolation pattern 41 may extend along the first conductive isolation pattern 43 and the second insulating isolation pattern 42 may extend along the second conductive isolation pattern 44. For example, the first insulating isolation pattern 41 and the second insulating isolation pattern 42 may be provided to conform to the inner surfaces of the first isolation trench DTI1_T and the second isolation trench DTI2_T, respectively.

The first and second insulating isolation patterns 41 and 42 may contain the same material. The first and second insulating isolation patterns 41 and 42 may contain a silicon-based insulating material or a high-dielectric constant material. For example, the silicon-based insulating material may include, but is not limited to, silicon nitride, silicon oxide, or silicon oxynitride. The high-dielectric constant material may include, but is not limited to, hafnium oxide or aluminum oxide. As another example, each of the first and second insulating isolation patterns 41 and 42 may include a plurality of layers, and the individual layers may contain different materials.

The first and second insulating isolation patterns 41 and 42 may have a refractive index lower than that of the first substrate 1. However, the materials that the first and second insulating isolation patterns 41 and 42 contain are not limited thereto, and may be variously changed.

The first conductive isolation pattern 43 may be provided on the first insulating isolation pattern 41, and the second conductive isolation pattern 44 may be provided on the second insulating isolation pattern 42. The first and second conductive isolation patterns 43 and 44 may be surrounded by the first insulating isolation pattern 41 and the second insulating isolation pattern 42, respectively. The first insulating isolation pattern 41 may be provided between the first conductive isolation pattern 43 and the first substrate 1, and the second insulating isolation pattern 42 may be provided between the second conductive isolation pattern 44 and the first substrate 1.

Since the first insulating isolation pattern 41 and the second insulating isolation pattern 42 extend so as to conform to the inner surfaces of the first isolation trench DTI1_T and the second isolation trench DTI2_T, respectively, as described above, the width relationship between the pixel isolation pattern DTI1 and the dummy isolation pattern DTI2 may be changed by the first conductive isolation pattern 43 and the second conductive isolation pattern 44 that are provided in the first isolation trench DTI1_T and the second isolation trench DTI2_T, respectively.

The maximum width and minimum width of the first conductive isolation pattern 43 of the pixel isolation pattern DTI1 may be smaller than the maximum width and minimum width of the second conductive isolation pattern 44 of the dummy isolation pattern DTI2, respectively.

Accordingly, the maximum width and minimum width of the pixel isolation pattern DTI1 may be smaller than the maximum width and minimum width of the dummy isolation pattern DTI2, respectively. For example, the above contents about the width relationship between the pixel isolation pattern DTI1 and the dummy isolation pattern DTI2 may be applied substantially equally to the width relationship between the first conductive isolation pattern 43 and the second conductive isolation pattern 44.

The first and second conductive isolation patterns 43 and 44 may contain the same material. The first and second conductive isolation patterns 43 and 44 may contain a crystalline semiconductor material such as polycrystalline silicon, and the first and second conductive isolation patterns 43 and 44 may further contain an impurity, which may contain an impurity of the first conductivity type or an impurity of a second conductivity type.

Here, the impurity of the first conductivity type may refer to a p-type impurity, and the impurity of the second conductivity type may refer to an n-type impurity.

As another example, the first and second conductive isolation patterns 43 and 44 may contain a crystalline semiconductor material such as undoped polycrystalline silicon. The term “undoped” may mean that no intentional doping process has been performed. However, the materials that the first and second conductive isolation patterns 43 and 44 contain are not limited thereto, and may be variously changed.

The isolation capping pattern 45 of the pixel isolation pattern DTI1 may be provided on the first conductive isolation pattern 43. The first conductive isolation pattern 43 and the isolation capping pattern 45 may be provided so as to overlap in the vertical direction, and the isolation capping pattern 45 may be provided adjacent to the first surface 1a of the first substrate 1.

According to an example embodiment illustrated in FIGS. 6 and 7, a surface of the isolation capping pattern 45 and the first surface 1a of the first substrate 1 are flat. However, the disclosure is not limited thereto, and as such, the surface of the isolation capping pattern 45 and the first surface 1a of the first substrate 1 may have curvatures or may be curved.

The isolation capping pattern 45 may contain a non-conductive material. The isolation capping pattern 45 may contain a silicon-based insulating material (for example, silicon nitride, silicon oxide, or silicon oxynitride) or a high-dielectric constant material (for example, hafnium oxide or aluminum oxide). However, the material that the isolation capping pattern 45 contains is not limited thereto, and may be variously changed.

The pixel isolation pattern DTI1 may be provided in the pixel area APS, the optical black area OB, and the contact region CR, and the dummy isolation pattern DTI2 may be provided in the contact region CR, and the pixel isolation pattern DTI1 and the dummy isolation pattern DTI2 may be connected to each other.

Some portions of the pixel isolation pattern DTI1 may be provided at the boundary between the optical black area OB and the contact region CR and the boundary between the contact region CR and the pad region PR.

The pixel isolation pattern DTI1 and the dummy isolation pattern DTI2 may include horizontal isolation pattern portions DTI1_H and DTI2_H extending in a first direction X parallel with the first substrate 1, respectively, and may include vertical isolation pattern portions DTI1_V and DTI2_V extending in a second direction Y intersecting the first direction X, respectively.

Accordingly, each of the pixel isolation pattern DTI1 and the dummy isolation pattern DTI2 may have a lattice structure on a plane.

According to an embodiment, the width of the horizontal isolation pattern portion DTI1_H of the pixel isolation pattern DTI1 in the second direction Y may be smaller than the width of the horizontal isolation pattern portion DTI2_H of the dummy isolation pattern DTI2 in the second direction Y.

Also, the width of the vertical isolation pattern portion DTI1_V of the pixel isolation pattern DTI1 in the first direction X may be smaller than the width of the vertical isolation pattern portion DTI2_V of the dummy isolation pattern DTI2 in the first direction X.

The width of the horizontal isolation pattern portion DTI2_H of the dummy isolation pattern DTI2 in the second direction Y may be substantially the same as the width of the vertical isolation pattern portion DTI2_V of the dummy isolation pattern DTI2 in the first direction X. However, this is an example, and the relationship between the horizontal isolation pattern portion DTI2_H and vertical isolation pattern portion DTI2_V of the dummy isolation pattern DTI2 is not limited thereto, and may be variously changed.

The pixel area APS may include the plurality of active pixels PX arranged two-dimensionally along the first direction X and the second direction Y. For example, as shown in FIG. 4, the plurality of active pixels PX may constitute a first active pixel group PG1, a second active pixel group PG2, a third active pixel group PG3, and a fourth active pixel group PG4.

Each of the first to fourth active pixel groups PG1, PG2, PG3, and PG4 may include (N×M)-number of active pixels PX in an N×M array. Each of N and M may be an integer greater than 1 independently.

As shown in FIG. 4, each of the first to fourth active pixel groups PG1, PG2, PG3, and PG4 may include four adjacent active pixels PX arranged in two rows and two columns. However, the number and arrangement of active pixels PX which are included in one active pixel group is not limited thereto, and may be variously changed. For example, each of the first to fourth active pixel groups PG1, PG2, PG3, and PG4 may include nine adjacent active pixels PX arranged in three rows and three columns. As another example, each of the first to fourth active pixel groups PG1, PG2, PG3, and PG4 may include sixteen adjacent active pixels PX arranged in four rows and four columns.

In the pixel area APS, the pixel isolation pattern DTI1 may be provided inside the first substrate 1, and may isolate and define the plurality of active pixels PX. For example, the pixel isolation pattern DTI1 may isolate and define the plurality of active pixels included in the first to fourth active pixel groups PG1, PG2, PG3, and PG4 as shown in FIG. 4. For example, the pixel isolation pattern DTI1 may have a lattice structure on a plane, and may partition a plurality of active pixels PX constituting each of the first to fourth active pixel groups PG1, PG2, PG3, and PG4.

The optical black area OB may include at least one black pixel OPX. In the optical black area OB, the pixel isolation pattern DTI1 may be provided inside the first substrate 1 and isolate and define the black pixels OPX. For example, the optical black area OB may include a first black pixel OPX1 and a second black pixel OPX2, and the first black pixel OPX1 and the second black pixel OPX2 may be isolated and defined by the pixel isolation pattern DTI1.

The dummy isolation pattern DTI2 may be provided in the contact region CR, and be connected to the dummy isolation contact CP. This will be described below in detail.

The element isolation pattern STI may be provided inside the first substrate 1. The element isolation pattern STI may be provided adjacent to the first surface 1a of the first substrate 1. The element isolation pattern STI may be a shallow trench isolation (STI) layer.

The element isolation pattern STI may be penetrated by the pixel isolation pattern DTI1. For example, the element isolation pattern STI may be provided at least on a portion of the side surface of the pixel isolation pattern DTI1. For example, the element isolation pattern STI may be provided so as to surround a portion of the side surface of the pixel isolation pattern DTI1. Also, the element isolation pattern STI may not be provided on the side surface of the dummy isolation pattern DTI2.

According to an embodiment, a width of the element isolation pattern STI decreases in a direction from the first surface 1a of the first substrate 1 to the second surface 1b. The element isolation pattern STI may be provided apart from the photoelectric converters PD.

According to an example embodiment illustrated in FIGS. 6 and 7, a surface of the element isolation pattern STI and the first surface 1a of the first substrate 1 are flat. However, the disclosure is not limited thereto, and as such, the surface of the element isolation pattern STI and the first surface 1a of the first substrate 1 may have curvatures or may be curved.

A photoelectric converter PD in the pixel area APS may be provided inside the first substrate 1 so as to correspond to each of a plurality of active pixels PX. Further, a photoelectric converter PD in the optical black area OB may be provided inside the first substrate 1 so as to correspond to some of a plurality of black pixels OPX1 and OPX2.

According to an embodiment, the optical black area OB may be an area where light does not enter the first substrate 1. A photoelectric converter PD in the optical black area OB may be provided inside the first substrate 1 so as to correspond to the first black pixel OPX1 and may not be provided inside the first substrate 1 corresponding to the second black pixel OPX2. For example, in the optical black area OB, an area of the first substrate 1 corresponding to the second black pixel OPX2 may be a dummy area undoped with an impurity.

The photoelectric converter PD in the optical black area OB that are provided inside the first substrate 1 so as to correspond to the first black pixel OPX1 may have a structure similar or identical to that of the photoelectric converter PD in the pixel area APS that is provided inside the first substrate 1 so as to correspond to an active pixel PX, but may not perform the same operation (i.e., an operation of receiving light and generating electrical signals) as that of the photoelectric converter PD that is provided so as to correspond to the active pixel PX.

The first black pixel OPX1 may sense the amount of charge, which may be generated from the photoelectric converter PD shielded from light, and provide a first reference charge amount. The first reference charge amount may become a relative reference value when the amounts of charge generated from the active pixels PX are calculated.

Further, in the optical black area OB, a signal generated in the dummy area of the first substrate 1 corresponding to the second black pixel OPX2 may be used as information for removing process noise thereafter. For example, the second black pixel OPX2 may sense the amount of charge, which may be generated in the state where there are no photoelectric converters PD, and provide a second reference charge amount. The second reference charge amount may be used as information for removing process noise.

The photoelectric converters PD may be regions in the first substrate 1, doped with an impurity of the second conductivity type. The impurity of the second conductivity type may have the opposite conductivity type to the impurity of the first conductivity type. For example, the impurity of the second conductivity type may include an n-type impurity such as phosphorus, arsenic, bismuth, and/or antimony. The n-type impurity implanted in a photoelectric converter PD may form a p-n junction with the p-type impurity implanted in the first substrate 1 to provide a photodiode.

The individual photoelectric converters PD may include first regions adjacent to the first surface 1a of the first substrate 1, and second regions adjacent to the second surface 1b. There may be a difference in impurity concentration between the first regions and second regions of the photoelectric converters PD.

Accordingly, the photoelectric converters PD may have a potential gradient between the first surface 1a and second surface 1b of the first substrate 1. However, in some embodiments, the photoelectric converters PD may have no potential gradient between the first surface 1a and second surface 1b of the first substrate 1.

In the pixel area APS and the optical black area OB, a transfer gate TG may be provided on the first surface 1a of the first substrate 1 so as to correspond to the active pixel PX and the black pixels OPX1 and OPX2. The transfer gate TG may be provided between the pixel isolation pattern DTI1 defining the active pixel PX and the black pixels OPX1 and OPX2.

According to an embodiment, the transfer gate TG may be a vertical type. A portion of a transfer gate TG may be provided inside the first substrate 1, and the other portion may be provided so as to protrude from the first surface 1a of the first substrate 1.

The transfer gate TG may include a first portion TGa that is provided on the first surface 1a of the first substrate 1, and a second portion TGb that is provided inside the first substrate 1 and extends from the first surface 1a of the first substrate 1 toward the second surface 1b.

According to an embodiment, a width of the second portion TGb of the transfer gate TG decreases from the first surface 1a of the first substrate 1 toward the second surface 1b. Accordingly, the second portion TGb of the transfer gate TG may have an inclined side surface. However, the shape of the transfer gate TG is not limited thereto, and may be variously changed. For example, the transfer gate TG may be a planar type in which the second portion TGb is omitted and only the first portion TGa is included.

According to some embodiments, gate spacers may be provided on both surfaces of the first portion TGa of the transfer gate TG. The gate spacers may contain, for example, silicon nitride, silicon carbonitride, or silicon oxynitride.

Between the transfer gate TG and the first substrate 1, a gate dielectric layer Gox may be provided. For example, the gate dielectric layer Gox may be provided between the second portion TGb of the transfer gate TG and the first substrate 1.

A floating diffusion zone FD may be provided on one side of the transfer gate TG inside the first substrate 1. The floating diffusion zone FD may be provided adjacent to the first surface 1a of the first substrate 1. The floating diffusion zone FD may be doped with an impurity of the second conductivity type. For example, the impurity of the second conductivity type may be an n-type impurity.

The image sensor 10 according to the embodiment may be a back-illuminated image sensor. Light may enter the first substrate 1 through the second surface 1b of the first substrate 1. By the incident light, electron-hole pairs may be generated at the p-n junctions. The generated electrons may migrate to the photoelectric converters PD. In an example case in which a voltage is applied to the transfer gate TG, the above-mentioned electrons may migrate to the floating diffusion zone FD.

As shown in FIG. 5, a reset gate RG may be provided adjacent to the transfer gates TG included in one of the plurality of active pixels PX and one of the black pixels OPX1 and OPX2, respectively.

A source follower gate SF and a selection gate SEL may be provided adjacent to the transfer gates TG included in another of the plurality of active pixels PX and another of the black pixels OPX1 and OPX2, respectively.

The above-mentioned gates TG, RG, SF, and SEL may correspond to transistors TX, RX, DX, and SX of FIG. 2, respectively. The gates TG, RG, SF, and SEL may be provided so as to overlap an active area ACT.

According to an embodiment, a reset transistor RX, a selection transistor SX, and a source follower transistor DX may be shared by two adjacent active pixels PX.

According to some embodiments, a reset transistor RX, a selection transistor SX, and a source follower transistor DX may be provided on the first surface 1a of the first substrate 1.

The plurality of dummy isolation contacts CP may be provided in the contact region CR. Each of the plurality of dummy isolation contacts CP may be connected to the dummy isolation pattern DTI2, in the contact region CR.

By a dummy isolation contact CP receiving a negative bias voltage from an external wiring line, the negative bias voltage may be applied to the dummy isolation pattern DTI2. For example, the negative bias voltage may be applied to the second conductive isolation pattern 44 of the dummy isolation pattern DTI2.

The second conductive isolation pattern 44 of the dummy isolation pattern DTI2 provided in the contact region CR and the first conductive isolation pattern 43 of the pixel isolation pattern DTI1 provided in a region other than the contact region CR may be electrically connected.

Accordingly, the negative bias voltage applied to the second conductive isolation pattern 44 of the dummy isolation pattern DTI2 connected to the dummy isolation contact CP may be transferred to the whole of the first conductive isolation pattern 43 of the pixel isolation pattern DTI1. For example, the dummy isolation pattern DTI2 connected to the dummy isolation contact CP may serve as a common bias line.

As the negative bias voltage is applied to the first conductive isolation pattern 43 of the pixel isolation pattern DTI1 as described above, holes that may exist on the surface of the pixel isolation pattern DTI1 may be fixed, whereby the dark current characteristic may be improved.

According to an embodiment, in the contact region CR, the plurality of dummy isolation contacts CP may be provided at the area where the horizontal isolation pattern portion DTI2_H and vertical isolation pattern portions DTI2_V of the dummy isolation pattern DTI2 intersect.

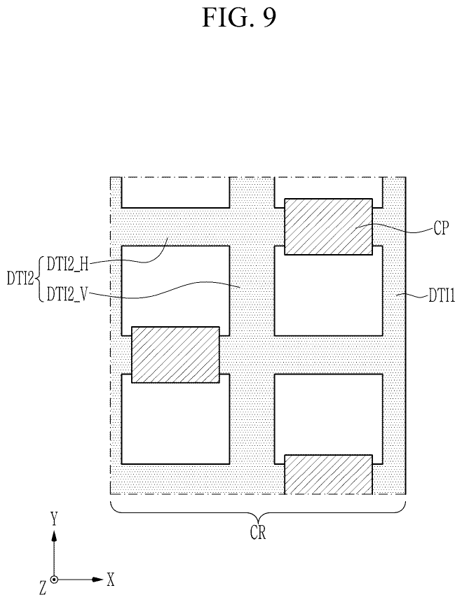

The plurality of dummy isolation contacts CP may be arranged in an island shape on a plane. For example, the plurality of dummy isolation contacts CP may be arranged side by side along the second direction Y so as to be spaced apart from each other on a plane. However, the area where a dummy isolation contact CP is provided, the arrangement relationship between the dummy isolation contact CP and the dummy isolation pattern DTI2, and the planer shape of the dummy isolation contact CP are not limited thereto, and may be variously changed. This will be described below in detail with reference to FIGS. 9 to 12.

According to an embodiment, the width of a dummy isolation contact CP in the first direction X may be greater than the width of the vertical isolation pattern portion DTI2_V of the dummy isolation pattern DTI2 in the first direction X, and the width of the dummy isolation contact CP in the second direction Y may be greater than the width of the horizontal isolation pattern portion DTI2_H in the second direction Y. However, the width relationship between the dummy isolation contact CP and the dummy isolation pattern DTI2 is not limited thereto, and may be variously changed.

The dummy isolation contact CP may be a vertical type. For example, a portion of the dummy isolation contact CP may be provided inside the first substrate 1, and the other portion may be provided so as to protrude from the first surface 1a of the first substrate 1.

The dummy isolation contact CP may include a first portion CPa that is provided on the first surface 1a of the first substrate 1, and a second portion CPb that is provided inside the first substrate 1 and extends from the first surface 1a of the first substrate 1 toward the second surface 1b.

The first portion CPa of the dummy isolation contact CP may be in direct contact with the first surface 1a of the first substrate 1. However, the disclosure is not limited thereto, and as such, according to another embodiment, one or more other layers may be further provided between the first portion CPa of the dummy isolation contact CP and the first substrate 1.

According to an embodiment, a width of the second portion CPb of the dummy isolation contact CP decreases from the first surface 1a of the first substrate 1 toward the second surface 1b. For example, the second portion CPb of the dummy isolation contact CP may have an inclined side surface.

The second portion CPb of the dummy isolation contact CP may recess a portion of the first substrate 1 from the first surface 1a toward the second surface 1b. The second portion CPb of the dummy isolation contact CP may be in direct contact with the dummy isolation pattern DTI2. For example, the dummy isolation contact CP may be in direct contact with the second insulating isolation pattern 42 and second conductive isolation pattern 44 of the dummy isolation pattern DTI2.

Further, as the second portion CPb of the dummy isolation contact CP is provided inside the first substrate 1, a portion of the dummy isolation contact CP may be in direct contact with the inner surface of the first substrate 1, and the other portion may be in direct contact with the dummy isolation pattern DTI2. However, the present disclosure is not limited thereto, and as such, according to another embodiment, one or more other layers may be further provided between the dummy isolation pattern DTI2 and the second portion CPb of the dummy isolation contact CP and/or between the first substrate 1 and the second portion CPb of the dummy isolation contact CP.

According to some embodiments, contact spacers may be provided on both side surfaces of the first portion CPa of the dummy isolation contact CP. The contact spacers may contain, for example, silicon nitride, silicon carbonitride, or silicon oxynitride.

As the transfer gate TG and the dummy isolation contact CP are formed together by the same process, the dummy isolation contact CP may contain the same material as that of the transfer gate TG. For example, the transfer gate TG and the dummy isolation contact CP may contain polycrystalline silicon. However, this is an example, and the material which the transfer gate TG and the dummy isolation contact CP contain may be variously changed.

Also, the dummy isolation contact CP may further contain an impurity of the first conductivity type. For example, the impurity of the first conductivity type may be a p-type impurity. As the dummy isolation contact CP is doped with the impurity of the first conductivity type, electrical resistance, which is generated when a negative bias voltage is applied to the second conductive isolation pattern 44 of the dummy isolation pattern DTI2, may be reduced.

According to an embodiment, the transfer gate TG and the dummy isolation contact CP may have different widths and different thicknesses.

For example, referring to FIG. 7, the transfer gate TG may include a first surface TG_S1 and a second surface TG_S2 facing each other, and the width T1 of the first surface TG_S1 of the transfer gate TG may be greater than the width T2 of the second surface TG_S2.

As the first portion TGa of the transfer gate TG has a flat shape extending in a direction parallel with the first surface 1a of the first substrate 1, and the second portion TGb has a shape whose width decreases in a direction from the first surface 1a of the first substrate 1 toward the second surface 1b, the transfer gate TG may have a maximum width at the first surface TG_S1 and have a minimum width at the second surface TG_S2.

The width T1 of the transfer gate TG at the first surface TG_S1 may refer to the width of the first portion TGa of the transfer gate TG, and the width T2 at the second surface TG_S2 may refer to the minimum width of the second portion TGb of the transfer gate TG.

The dummy isolation contact CP may include a first surface CP_S1 and a second surface CP_S2 facing each other. The width T3 of the first surface CP_S1 of the dummy isolation contact CP may be greater than the width T4 of the second surface CP_S2.

Similar to the transfer gate TG, as the first portion CPa of the dummy isolation contact CP has a flat shape extending in a direction parallel with the first surface 1a of the first substrate 1, and the second portion CPb has a shape whose width decreases in a direction from the first surface 1a of the first substrate 1 toward the second surface 1b, the dummy isolation contact CP may have a maximum width at the first surface CP_S1 and have a minimum width at the second surface CP_S2.

The width T3 of the dummy isolation contact CP at the first surface CP_S1 may refer to the width of the first portion CPa of the dummy isolation contact CP, and the width T4 at the second surface CP_S2 may refer to the minimum width of the second portion CPb of the dummy isolation contact CP.

According to an embodiment, the width T1 of the first surface TG_S1 of the transfer gate TG may be smaller than the width T3 of the first surface CP_S1 of the dummy isolation contact CP. For example, the width of the first portion TGa of the transfer gate TG may be smaller than the width of the first portion CPa of the dummy isolation contact CP.

Further, the width T2 of the second surface TG_S2 of the transfer gate TG may be smaller than the width T4 of the second surface CP_S2 of the dummy isolation contact CP. For example, the minimum width of the second portion TGb of the transfer gate TG may be smaller than the minimum width of the second portion CPb of the dummy isolation contact CP.

As each of the second portion TGb of the transfer gate TG and the second portion CPb of the dummy isolation contact CP has a shape whose width decreases in a cross section, in an example case in which the minimum width of the second portion TGb of the transfer gate TG is smaller than the minimum width of the second portion CPb of the dummy isolation contact CP, the maximum width of the second portion TGb of the transfer gate TG may be smaller than the maximum width of the second portion CPb of the dummy isolation contact CP.

As shown in FIG. 7, the first portion TGa of the transfer gate TG may have a first thickness D1, and the second portion TGb may have a second thickness D2. The first portion CPa of the dummy isolation contact CP may have a third thickness D3, and the second portion CPb may have a fourth thickness D4. Here, the first to fourth thicknesses D1, D2, D3, and D4 may refer to thicknesses along a third direction Z which is a direction perpendicular to the first substrate 1.

According to an embodiment, the first thickness D1 may be substantially equal to the third thickness D3, and the second thickness D2 may be smaller than the fourth thickness D4. For example, the thickness of the first portion TGa of the transfer gate TG may be substantially equal to the thickness of the first portion CPa of the dummy isolation contact CP, and the thickness of the second portion TGb of the transfer gate TG may be smaller than the thickness of the second portion CPb of the dummy isolation contact CP.

Accordingly, the second surface TG_S2 of the transfer gate TG and the second surface CP_S2 of the dummy isolation contact CP may be provided at different levels. For example, the second surface TG_S2 of the transfer gate TG may be provided closer to the second surface 1b of the first substrate 1 than the second surface CP_S2 of the dummy isolation contact CP. For example, the end of the second portion TGb of the transfer gate TG may be provided closer to the second surface 1b of the first substrate 1 than the end of the second portion CPb of the dummy isolation contact CP.

Further, as the gate dielectric layer Gox is provided between the first portion TGa of the transfer gate TG and the first surface 1a of the first substrate 1, the first surface TG_S1 of the transfer gate TG and the first surface CP_S1 of the dummy isolation contact CP may be provided at different levels. For example, the first surface TG_S1 of the transfer gate TG may be provided farther from the first surface 1a of the first substrate 1 than the first surface CP_S1 of the dummy isolation contact CP. However, the width and thickness relationships between the transfer gate TG and the dummy isolation contact CP are not limited thereto, and may be variously changed.

As the second portion CPb of the dummy isolation contact CP extends from the first portion CPa toward the second surface 1b of the first substrate 1 and recesses a portion of the first substrate 1 and a portion of the dummy isolation pattern DTI2 as described above, the height of the dummy isolation pattern DTI2 that is in direct contact with the dummy isolation contact CP may be smaller than the height of the dummy isolation pattern DTI2 that is not in direct contact with the dummy isolation contact CP.

In the contact region CR, the dummy isolation pattern DTI2 that is in direct contact with the dummy isolation contact CP may include a second surface DTI2_S2 and a third surface DTI2_S3 facing each other. Here, the second surface DTI2_S2 of the dummy isolation pattern DTI2 may refer to a surface that is in contact with the second surface 1b of the first substrate 1, and the third surface DTI2_S3 may refer to a surface that is in direct contact with the dummy isolation contact CP.

The dummy isolation pattern DTI2 that is in direct contact with the dummy isolation contact CP may have a minimum width at the second surface DTI2_S2 and have a maximum width at the third surface DTI2_S3. For example, the width W5 of the third surface DTI2_S3 of the dummy isolation pattern DTI2 that is in direct contact with the dummy isolation contact CP may be greater than the width W4 of the second surface DTI2_S2.

According to an embodiment, the width W4 of the second surface DTI2_S2 of the dummy isolation pattern DTI2 that is in direct contact with the dummy isolation contact CP and the width W5 of the third surface DTI2_S3 may be smaller than the width T4 of the second surface CP_S2 of the dummy isolation contact CP. For example, the maximum width of the dummy isolation pattern DTI2 that is in direct contact with the dummy isolation contact CP may be smaller than the minimum width of the dummy isolation contact CP.

According to an embodiment, the third surface DTI2_S3 of the dummy isolation pattern DTI2 may be provided on the second surface CP_S2 of the dummy isolation contact CP. For example, the second surface CP_S2 of the dummy isolation contact CP may entirely covered by the third surface DTI2_S3 of the dummy isolation pattern DTI2. That is, the dummy isolation contact CP may be in direct contact with one surface of the second conductive isolation pattern 44 of the dummy isolation pattern DTI2, and entirely cover one surface of the second conductive isolation pattern 44.

In an example case in which the minimum width of the dummy isolation contact CP is greater than the maximum width of the dummy isolation pattern DTI2 that is in direct contact with the dummy isolation contact CP, in an operation of forming the dummy isolation contact CP, even if the center of the dummy isolation contact CP and the center of the dummy isolation pattern DTI2 are misaligned, the dummy isolation contact CP may be in direct contact with the second conductive isolation pattern 44 of the dummy isolation pattern DTI2 and be electrically connected thereto.

In some embodiments, the width T4 of the second surface CP_S2 of the dummy isolation contact CP may be smaller than the width W5 of the third surface DTI2_S3 of the dummy isolation pattern DTI2. For example, the minimum width of the second portion CPb of the dummy isolation contact CP may be smaller than the maximum width of the dummy isolation pattern DTI2 that is in direct contact with the dummy isolation contact CP.

In an example case in which the width T4 of the second surface CP_S2 of the dummy isolation contact CP is smaller than the width W5 of the third surface DTI2_S3 of the dummy isolation pattern DTI2, a portion of the second portion CPb of the dummy isolation contact CP may recess a portion of the second conductive isolation pattern 44 of the dummy isolation pattern DTI2 and be provided inside the dummy isolation pattern DTI2. Accordingly, the portion of the second portion CPb of the dummy isolation contact CP may be surrounded by the second conductive isolation pattern 44 of the dummy isolation pattern DTI2.

Referring to FIG. 6 again, the first chip CH1 may further include an upper interlayer insulating layer IL that is provided on the first surface 1a of the first substrate 1. For example, the upper interlayer insulating layer IL may cover the first surface 1a of the first substrate 1.

The upper interlayer insulating layer IL may include first to fifth upper interlayer insulating layers IL1, IL2, IL3, IL4, and IL5 that are provided between the first surface 1a of the first substrate 1 and the second chip CH2.

Each of the first to fifth upper interlayer insulating layers IL1, IL2, IL3, IL4, and IL5 may include at least one of, for example, silicon oxide films, silicon nitride films, silicon oxynitride films, and porous low dielectric films. However, the number and materials of layers that are included in the upper interlayer insulating layer IL are not limited thereto, and may be variously changed.

Between or inside the first to fifth upper interlayer insulating layers IL1, IL2, IL3, IL4, and IL5, first wiring lines 12 may be provided. The first wiring lines 12 may contain a conductive material such as copper (Cu).

The first wiring lines 12 may be connected to one another by intermediate contacts 19 that are provided inside the first to fifth upper interlayer insulating layers IL1, IL2, IL3, IL4, and IL5.

In the optical black area OB, connection wiring lines 14 may be provided between or inside the first to fifth upper interlayer insulating layers IL1, IL2, IL3, IL4, and IL5. The first wiring lines 12 and the connection wiring lines 14 may contain the same material.

The connection wiring lines 14 and the intermediate contacts 19 between them may constitute a connection wiring structure CS. The connection wiring structure CS may include a plurality of connection wiring lines 14, but is not limited thereto and may include only one connection wiring line 14.

The first chip CH1 may further include a first upper contact plug 31, a second upper contact plug 33, and a third upper contact plug 35 which are provided inside the first upper interlayer insulating layer IL1.

The first upper contact plug 31 may pass through the first upper interlayer insulating layer IL1 in the pixel area APS and connect a transfer gate TG provided on the first surface 1a of the first substrate 1 and a first wiring line 12.

The second upper contact plug 33 may pass through the first upper interlayer insulating layer IL1 in the pixel area APS and connect a floating diffusion zone FD provided adjacent to the first surface 1a of the first substrate 1 and a first wiring line 12.

The third upper contact plug 35 may pass through the first upper interlayer insulating layer IL1 in the optical black area OB and connect the dummy isolation contact CP and the connection wiring structure CS.

The first upper contact plug 31, the second upper contact plug 33, and the third upper contact plug 35 may contain a conductive material such as tungsten, titanium nitride, tantalum nitride, and tungsten nitride.

The first chip CH1 may further include a first upper connection pad 22, a second upper connection pad 24, and a third upper connection pad 26 which are provided inside the fifth upper interlayer insulating layer IL5. Also, the first chip CH1 may further include first and second metal pads 32 and 34 which are provided inside the fifth upper interlayer insulating layer IL5.

The first to third upper connection pads 22, 24, and 26 may be provided inside the fifth upper interlayer insulating layer IL5. The first to third upper connection pads 22, 24, and 26 are exposed from one surface of the first chip CH1 facing the second chip CH2 and be in direct contact with lower connection pads 122, 124, 126 of the second chip CH2.

The first and second metal pads 32 and 34 may be provided between the first to third upper connection pads 22, 24, and 26 and the fourth upper interlayer insulating layer IL4. The first and second metal pads 32 and 34 may be connected to the first to third upper connection pads 22, 24, and 26.

The first metal pad 32 may be provided in the pixel area APS, and the second metal pad 34 may be provided in the peripheral area ER. For example, the second metal pad 34 may be provided so as to extend from the contact region CR to the pad region PR.

The first metal pad 32 may be provided on the active pixels PX in the pixel area APS. For example, the first metal pad 32 may cover the active pixels PX provided in the pixel area APS. For example, the first metal pad 32 may shield a noise caused by an electromagnetic field induced by an operation of circuits in the second chip CH2. Further, during an operation of the image sensor, a ground voltage may be applied to the first metal pad 32.

The second metal pad 34 that is provided in the peripheral area ER may be directly connected to the third upper connection pad 26. The second metal pad 34 may be connected to a circuit outside the chip by wire bonding or the like.

As shown in FIG. 3, the image sensor 10 according to the embodiment may include a plurality of second metal pads 34. The plurality of second metal pads 34 may be arranged in an island shape along the pad region PR on a plane.

The first chip CH1 may further include a first lower contact plug 15 and a second lower contact plug 17 which connect the first wiring lines 12 and the first and second metal pads 32 and 34.

The first lower contact plug 15 may connect a first wiring line 12 and the first metal pad 32 in the pixel area APS. The second lower contact plug 17 may connect the second metal pad 34 and the connection wiring structure CS in the contact region CR.

The first lower contact plug 15 and the second lower contact plug 17 may contain a conductive material different from that of the first wiring lines 12. The first lower contact plug 15 and the second lower contact plug 17 may contain at least one of, for example, tungsten, titanium, tantalum, and conductive nitrides thereof.

The first and second metal pads 32 and 34 may contain a conductive material different from that of the first to third upper connection pads 22, 24, and 26. The first and second metal pads 32 and 34 may contain aluminum (Al).

The image sensor 10 according to the embodiment may further include a backside insulating layer 51, a diffusion prevention pattern 53, a first optical black pattern 55, a passivation layer 57, a grid pattern 60, color filters CF1 and CF2, a second optical black pattern CFB, and the micro lens layer MLL which are provided on the second surface 1b of the first substrate 1.

The backside insulating layer 51 may include at least one of a bottom antireflective coating (BARC) layer, a fixed charge layer, an adhesive layer, an antireflective layer, and a protective layer.

The fixed charge layer may include a metal oxide film or a metal fluoride film. The metal fluoride film may contain oxygen or fluorine whose amount is less than its stoichiometric ratio. Accordingly, the fixed charge layer may have negative fixed charge.

The fixed charge layer may contain metal oxide or metal fluoride containing at least one metal of hafnium (Hf), zirconium (Zr), aluminum (AI), tantalum (Ta), titanium (Ti), yttrium, and lanthanides.

According to an example embodiment, hole accumulation may occur around the fixed charge layer, and therefore, it is possible to effectively reduce occurrence of dark current and white spots.

The antireflective layer may prevent reflection of light such that incident light on the second surface 1b of the first substrate 1 can smoothly reach a photoelectric converter PD. For example, the antireflective layer may contain metal oxide (e.g., aluminum oxide or hafnium oxide) or silicon-based insulating material (e.g., silicon oxide or silicon nitride).

An exposure opening OR may expose at least a portion of the second metal pad 34 in the pad region PR.

The exposure opening OR may pass through the first substrate 1 and the upper interlayer insulating layer IL in the pad region PR and expose the upper surface of the second metal pad 34. The inner side wall of the exposure opening OR may be aligned with the side surface of the backside insulating layer 51 at substantially the same boundary. The width of the exposure opening OR may increase as the distance from the second metal pad 34 increases.

According to some embodiments, in the pad region PR, a pad isolation pattern, which surrounds the exposure opening OR and has a structure identical or similar to that of the pixel isolation pattern DTI1 or the dummy isolation pattern DTI2 may be further provided.

In the optical black area OB and the contact region CR, on the backside insulating layer 51, the diffusion prevention pattern 53 and the first optical black pattern 55 may be sequentially provided.

The diffusion prevention pattern 53 may contain a metal nitride such as TiN, TaN, or WN, and the first optical black pattern 55 may contain a conductive material such as tungsten (W).

In the pixel area APS, on the backside insulating layer 51, the color filters CF1 and CF2 and the grid pattern 60 may be provided.

As shown in FIG. 4, the color filter CF that is provided in the pixel area APS may include primary color filters.

The color filter CF may include a first color filter CF1, a second color filter CF2, and a third color filter CF3 having colors different from one another. For example, the first color filter CF1 may be a green color filter, the second color filter CF2 may be a red color filter, and the third color filter CF3 may be a blue color filter. As another example, the first color filter CF1 may be a cyan color filter, the second color filter CF2 may be a magenta color filter, and the third color filter CF3 may be a yellow color filter.

According to an embodiment, the color filters CF that are provided in the pixel area APS may have a Bayer pattern on a plane. For example, the color filters CF may have a pattern in which the number of first color filters CF1 is about twice the number of second color filters CF2 or the number of third color filters CF3.

According to an embodiment, the Bayer pattern may include two first color filters CF1 which are disposed diagonally to each other and a second color filter CF2 and a third color filter CF3 which are disposed diagonally to each other, in color filters CF, arranged in a 2×2 form on a plane, on one of the active pixel groups PG1, PG2, PG3, and PG4 each including active pixels arranged in a 2×2 form on a plane.

In the color filter CF provided on one of the active pixel groups PG1, PG2, PG3, and PG4, the ratio of first color filters CF1, second color filters CF2, and third color filters CF3 may be about 2:1:1.

The first color filters CF1, the second color filter CF2, and the third color filter CF3 may be provided so as to correspond to the plurality of active pixels PX, respectively. For example, the first color filters CF1, the second color filter CF2, and the third color filter CF3 may be provided so as to overlap the photoelectric converters PD provided so as to correspond to the plurality of active pixels PX, respectively. For example, the first color filters CF1, the second color filter CF2, and the third color filter CF3 may be provided on the photoelectric converters PD, respectively.

Each of the second color filter CF2 and the third color filter CF3 may be provided between adjacent first color filters CF1. The color filters CF of the Bayer pattern type may be repeatedly arranged along the first direction X and the second direction Y. However, the planer arrangement form of the color filters CF is not limited thereto, and may be variously changed.

The grid pattern 60 may be provided between the color filters CF1 and CF2 adjacent to each other, and isolate the color filters CF1 and CF2 adjacent to each other.

The grid pattern 60 may be provided so as to overlap a portion of the pixel isolation pattern DTI1 in the third direction Z which is the vertical direction. For example, the grid pattern 60 and the color filters CF1 and CF2 may be shifted from the center portions of the photoelectric converters PD. For example, the center portion of the grid pattern 60 and the center portions of the color filters CF1 and CF2 may be shifted in the first direction X from the center portion of each photoelectric converter PD. However, the arrangement relationship between the grid pattern 60 and the pixel isolation pattern DTI1 is not limited thereto, and may be variously changed. For example, the grid pattern 60 may be provided so as to completely overlap the pixel isolation pattern DTI1 in the vertical direction. As another example, the grid pattern 60 may be shifted so as not to overlap the pixel isolation pattern DTI1.

The degrees to which the grid pattern 60 and the color filters CF1 and CF2 are shifted from the center portions of the photoelectric converters PD may increase as the distance from the center portion of the first substrate 1 increases (e.g., in a direction toward the peripheral portion of the first substrate 1).

This is for correcting light obliquely entering areas other than the center portion of the first substrate 1 such that the oblique incident light can be centered on the center of each active pixel PX.

The color filters CF1 and CF2 may be provided on the upper surface of the grid pattern 60. For example, the upper surface of the grid pattern 60 may be covered by the color filters CF1 and CF2 adjacent to each other. For example, a portion of the upper surface of the grid pattern 60 may be covered by the first color filter CF1 and the other portion may be covered by the second color filter CF2. However, the arrangement relationship between the grid pattern 60 and the color filter CF is not limited thereto, and may be variously changed.

The grid pattern 60 may include a first grid pattern 62 and a second grid pattern 64 sequentially stacked. The thickness of the first grid pattern 62 in the third direction Z may be different from the thickness of the second grid pattern 64 in the third direction Z.

For example, the thickness of the first grid pattern 62 in the third direction Z may be smaller than the thickness of the second grid pattern 64 in the third direction Z. However, the relationship between the thickness of the first grid pattern 62 and the thickness of the second grid pattern 64 is not limited thereto, and may be variously changed.

According to an embodiment, the first grid pattern 62 and the second grid pattern 64 may contain different materials.

The first grid pattern 62 may contain at least one of metal materials or metal nitrides. For example, the first grid pattern 62 may contain at least one of titanium (Ti), titanium nitride (TiN), tungsten (W), aluminum (AI), and copper (Cu).

The second grid pattern 64 may contain a material having a refractive index lower than that of the color filter CF. For example, the second grid pattern 64 may contain an organic material, such as a polymer layer containing silica nanoparticles. However, the materials which the first grid pattern 62 and the second grid pattern 64 contain are not limited thereto, and may be variously changed.

In the example embodiment of FIG. 6, the grid pattern 60 includes two layers. However, the disclosure is not limited thereto, and as such, the number of layers which are included in the grid pattern 60 is not limited thereto, and may be variously changed. For example, the grid pattern 60 may include a single layer.

In the optical black area OB and the contact region CR, the second optical black pattern CFB may be provided on the backside insulating layer 51. The second optical black pattern CFB may contain, for example, the same material as that of the blue color filter.

The passivation layer 57 may be provided between the color filters CF1 and CF2 and the backside insulating layer 51, between the grid pattern 60 and the color filters CF1 and CF2, and between the second optical black pattern CFB and the first optical black pattern 55.

The passivation layer 57 may contain an insulating material such as a high-dielectric constant material. For example, the passivation layer 57 may contain aluminum oxide or hafnium oxide.

The micro lens layer MLL may be provided on the pixel area APS, the optical black area OB, and the contact region CR. For example, the pixel area APS, the optical black area OB, and the contact region CR may be covered by the micro lens layer MLL. Unlike in FIG. 6, the micro lens layer MLL may be provided so as to extend to the pad region PR.

The micro lens layer MLL may include a plurality of micro lenses ML which is provided on the color filter CF in the pixel area APS, and a flat portion MLP which is provided on the pixel area APS, the optical black area OB, and the contact region CR.

A micro lens ML and the flat portion MLP may contain the same material, and may be integrally formed.

The flat portion MLP of the micro lens layer MLL may correspond to a portion remaining after the micro lenses ML have been removed from the micro lens layer MLL. The upper surface of the flat portion MLP may have substantially a flat surface.

The upper surface of a micro lens ML may include a convex curved surface for refracting and condensing incident light from the outside, unlike the upper surface of the flat portion MLP. However, the shape of the micro lens ML is not limited thereto, and may be variously changed. For example, the upper surface of the micro lens ML may have a rectangular shape with rounded corners.

In the pixel area APS, the center portion of the micro lens ML may be shifted in the first direction X so as to be misaligned with each of the center portion of the first color filter CF1 and the center portion of the second color filter CF2. For example, the thickest portion of the micro lens ML may be provided so as to be misaligned with each of the center portion of the first color filter CF1 and the center portion of the second color filter CF2.

Also, the micro lens ML may be relatively further shifted in the first direction X from the center portion of the photoelectric converter PD as compared to the grid pattern 60 and the color filters CF1 and CF2.

Accordingly, the photoelectric converters PD, the color filters CF1 and CF2, and the micro lens ML may be provided such that they overlap but their center portions are misaligned.

Here, “overlapping” may mean not only an overlap relationship in the third direction Z which is the vertical direction but also an overlapping relationship in the propagation direction of incident light from the photoelectric converters PD. For example, the photoelectric converter PD, the color filters CF1 and CF2, and the micro lens ML may be provided so as to overlap along the direction of the path of incident light from the outside to the photoelectric converter PD. For example, as the center portion of the photoelectric converter PD, the center portion of the color filters CF1 and CF2, and the center portion of the micro lens ML are provided so as to be misaligned with one another, the center portion of the photoelectric converter PD, the center portion of the color filters CF1 and CF2, and the center portion of the micro lens ML may be provided the extension line of the path of light entering the photoelectric converter PD.

This is for correcting light obliquely entering areas other than the center portion of the first substrate 1 such that the oblique incident light can be centered on the center of each active pixel PX as described above.

The second chip CH2 may include a second substrate 100, a plurality of transistors TR provided in the second substrate 100, a lower interlayer insulating layer 110. The lower interlayer insulating layer 110 may be provided on the second substrate 100, second wiring lines 112, and lower connection pads 122, 124, and 126. For example, the lower interlayer insulating layer 110 may cover the second substrate 100, the second wiring lines 112 that are provided inside the lower interlayer insulating layer 110, and the lower connection pads 122, 124, and 126 that are connected to the uppermost ones of the second wiring lines 112.

The lower interlayer insulating layer 110 may have a single layer or multiple layer structure of at least one of silicon oxide layers, silicon nitride layers, silicon oxynitride layers, and porous insulating layers.

The lower connection pads 122, 124, and 126 may contain the same conductive material as that of the upper connection pads 22, 24, and 26, such as copper.

The lower connection pads 122, 124, and 126 may be exposed from one surface of the second chip CH2 facing the first chip CH1 and be in direct contact with the upper connection pads 22, 24, and 26 of the first chip CH1.

According to some embodiments, a bonding insulating layer may be further provided at the interface between the first chip CH1 and the second chip CH2. For example, the first chip CH1 may include an upper bonding insulating layer at the interface with the second chip CH2, and the second chip CH2 may include a lower bonding insulating layer at the interface with the first chip CH1, and the upper bonding insulating layer and the lower bonding insulating layer may be in direct contact with each other. For example, the upper bonding insulating layer and the lower bonding insulating layer may contain at least one of SiCN, SiOCN, and SiC.

The lower connection pads 122, 124, and 126 may include the first lower connection pad 122 that is connected to the first upper connection pad 22, the second lower connection pad 124 that is connected to the second upper connection pad 24, and the third lower connection pad 126 that is connected to the third upper connection pad 26.

Some of the first to third upper connection pads 22, 24, and 26 may include contact vias thereon. For example, as shown in FIG. 6, a portion of the first upper connection pad 22 may be connected to the first metal pad 32 through the a contact via, and a portion of the third upper connection pad 26 may be connected to the second metal pad 34 through a contact via.

The second chip CH2 may further include first vias 113 which connect the plurality of transistors TR and the second wiring lines 112 and second vias 115 which connect at least some of the second wiring lines 112 to one another, inside the lower interlayer insulating layer 110.

According to the image sensor 10 of the embodiment, since the width of the dummy isolation contact CP is greater than the width of the dummy isolation pattern DTI2 in the pixel area APS and the contact region CR provided outside the optical black area OB, it is possible to minimize the electrical resistance between the dummy isolation pattern DTI2 and the dummy isolation contact CP while improving the dark current characteristic of the image sensor 10, thereby improving the electrical characteristics of the image sensor 10. For example, the dummy isolation contact CP is connected to an external wiring line and applies a negative bias voltage to the dummy isolation pattern DTI2.

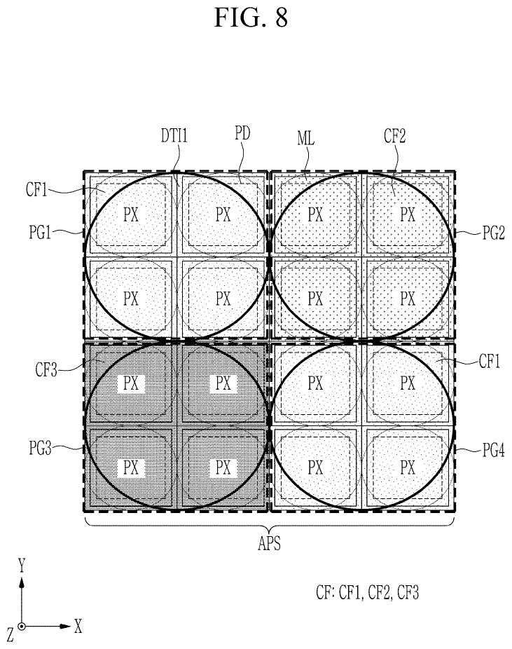

Hereinafter, image sensors according to various embodiment will be described with reference to FIGS. 8 to 12. In the following embodiments, components identical to those in the above-described embodiment will be denoted by the same reference symbols, and a redundant description thereof will not be made or will be made in brief, and the differences in them from the above-described embodiment will be mainly described.

FIG. 8 is a plan view illustrating a pixel area of an image sensor according to some embodiments.

The embodiment shown in FIG. 8 is different from the embodiment shown in FIG. 4 in the arrangement form of the color filter CF and the micro lens ML.

For example, referring to FIG. 8, the color filters which are provided in the pixel area APS may include (N×M)-number of color filters in an N×M array. Each of N and M may be an integer greater than 1 independently. For example, each of N and M may be 2 such that the color filters have a 2×2 tetra pattern on a plane. As another example, each of N and M may be 3 such that the color filters have a 3×3 nona pattern on a plane.

In some embodiments, the color filter CF may include the first color filter CF1 that is provided so as to correspond to the first active pixel group PG1, the second color filter CF2 that is provided so as to correspond to the second active pixel group PG2, the third color filter CF3 that is provided so as to correspond to the third active pixel group PG3, and the first color filter CF1 that is provided so as to correspond to the fourth active pixel group PG4.

The color filters CF may include two first color filters CF1 which are disposed diagonally to each other and the second color filter CF2 and the third color filter CF3 which are disposed diagonally to each other, and may have a pattern in which the number of first color filters CF1 is about twice the number of second color filters CF2 or the number of third color filters CF3. For example, the color filters CF may have a Bayer pattern on a plane. However, this is an example, and the arrangement form of the color filter CF is not limited thereto and may be variously changed.

According to the present embodiment, each of the first to third color filters CF1, CF2, and CF3 may overlap a plurality of active pixels PX, unlike the embodiment shown in FIG. 4 in which each of the first to third color filters CF1, CF2, and CF3 is provided so as to correspond to one active pixel PX. One color filter CF may be provided so as to correspond to four adjacent active pixels PX arranged in two rows and two columns. However, the number of active pixels PX which overlap a color filter CF is not limited thereto and may be variously changed.

For example, one color filter CF may be provided so as to correspond to nine adjacent active pixels PX arranged in three rows and three columns. As another example, one color filter CF may be provided so as to correspond to sixteen adjacent active pixels PX arranged in four rows and four columns.

According to the embodiment shown in FIG. 8, each of the first to fourth active pixel groups PG1, PG2, PG3, and PG4 may overlap one micro lens ML. For example, one micro lens ML may be provided so as to overlap each of the first to fourth active pixel groups PG1, PG2, PG3, and PG4 each include a plurality of active pixels. For example, one micro lens ML may be provided so as to correspond to four adjacent active pixels PX arranged in two rows and two columns. However, the number of active pixels PX which overlap one micro lens ML is not limited thereto and may be variously changed.

For example, one micro lens ML may be provided so as to correspond to nine adjacent active pixels PX arranged in three rows and three columns. As another example, one micro lens ML may be provided so as to correspond to sixteen adjacent active pixels PX arranged in four rows and four columns.

FIGS. 9 to 12 are plan views illustrating contact regions of image sensors according to some embodiments.

In FIGS. 9 to 12 the arrangement relationship between the dummy isolation contact CP and the dummy isolation pattern DTI2 are different from the arrangement relationship between the dummy isolation contact CP and the dummy isolation pattern DTI2 shown in FIG. 5.

According to the embodiment shown in FIG. 9, in the contact region CR, the plurality of dummy isolation contacts CP may be arranged so as to be connected to the horizontal isolation pattern portion DTI2_H of the dummy isolation pattern DTI2.

For example, the plurality of dummy isolation contacts CP may be arranged so as to overlap the horizontal isolation pattern portion DTI2_H of the dummy isolation pattern DTI2 and so as not to overlap the pixel isolation pattern DTI1 and the vertical isolation pattern portion DTI2_V of the dummy isolation pattern DTI2.

In the present embodiment, the plurality of dummy isolation contacts CP may be arranged in a zigzag form on the horizontal isolation pattern portion DTI2_H along the second direction Y on a plane in respect to the vertical isolation pattern portion DTI2_V of the dummy isolation pattern DTI2. However, the planer arrangement form of the plurality of dummy isolation contacts CP that is provided on the horizontal isolation pattern portion DTI2_H is not limited thereto, and may be variously changed. For example, the plurality of dummy isolation contacts CP may be provided so as to overlap the horizontal isolation pattern portion DTI2_H of the dummy isolation pattern DTI2 and be arranged side by side along the first direction X and/or the second direction Y.

According to an example embodiment in FIG. 9, the dummy isolation contacts CP are arranged in an island shape as seen in a plan view, on the horizontal isolation pattern portion DTI2_H of the dummy isolation pattern DTI2. However, the disclosure is not limited thereto, and as such, the planer shape of a dummy isolation contact CP may be variously changed.

For example, a dummy isolation contact CP may have a line shape on a plane. For example, the dummy isolation contact CP may extend in a line shape along the first direction X, and overlap the horizontal isolation pattern portion DTI2_H that is provided on one side of the vertical isolation pattern portion DTI2_V, the area where the vertical isolation pattern portion DTI2_V and the horizontal isolation pattern portion DTI2_H intersect each other, and the horizontal isolation pattern portion DTI2_H that is provided on the other side of the vertical isolation pattern portion DTI2_V.

Accordingly, the plurality of dummy isolation contacts CP may extend in the first direction X along the plurality of horizontal isolation pattern portions DTI2_H, and be arranged so as to be spaced from each other along the second direction Y.

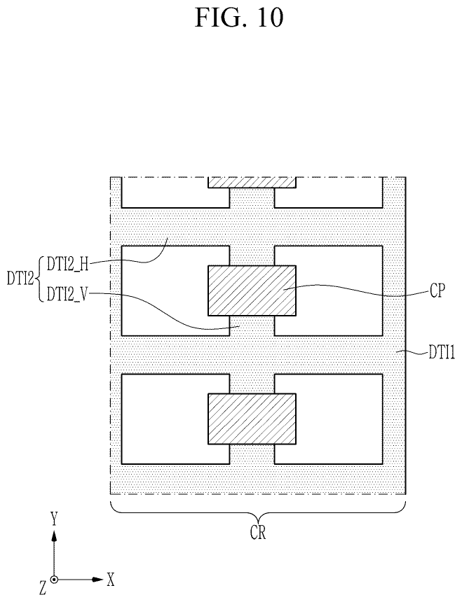

According to the embodiment shown in FIG. 10, in the contact region CR, a plurality of dummy isolation contacts CP may be arranged so as to be connected to the vertical isolation pattern portion DTI2_V of the dummy isolation pattern DTI2, unlike in the embodiment shown in FIG. 9. For example, the plurality of dummy isolation contacts CP may be arranged so as to overlap the vertical isolation pattern portion DTI2_V of the dummy isolation pattern DTI2 and not to overlap the pixel isolation pattern DTI1 and the horizontal isolation pattern portion DTI2_H of the dummy isolation pattern DTI2.

In the present embodiment, the plurality of dummy isolation contacts CP may be provided apart from each other so as to overlap the vertical isolation pattern portion DTI2_V of the dummy isolation pattern DTI2 and be arranged in an island shape on a plane. The plurality of dummy isolation contacts CP may be arranged side by side along the second direction Y which is the extension direction of the vertical isolation pattern portion DTI2_V.

According to an example embodiment in FIG. 10, the number of vertical isolation pattern portions DTI2_V of a dummy isolation pattern DTI2 is one. However, the disclosure is not limited thereto, and as such, the number of vertical isolation pattern portions DTI2_V may be variously changed. For example, a dummy isolation pattern DTI2 may extend in the second direction Y and include a plurality of vertical isolation pattern portions DTI2_V spaced apart from each other in the first direction X, and a plurality of dummy isolation contacts CP may be provided on each of the plurality of vertical isolation pattern portions DTI2_V.

In some embodiments, a dummy isolation contact CP may have a line shape on a plane, and extend along the second direction Y which is the extension direction of the vertical isolation pattern portion DTI2_V. In an example case in which the dummy isolation contact CP has a line shape on a plane and the width of the dummy isolation contact CP in the first direction X is greater than the width of the vertical isolation pattern portion DTI2_V in the first direction X, the dummy isolation contact CP may overlap some portions of the horizontal isolation pattern portion DTI2_H provided on both sides of the vertical isolation pattern portion DTI2_V.

Also, in some embodiments, some of the plurality of dummy isolation contacts CP may be provided so as to overlap the horizontal isolation pattern portion DTI2_H of the dummy isolation pattern DTI2 as in the embodiment shown in FIG. 9, and the others may be provided so as to overlap the vertical isolation pattern portion DTI2_V of the dummy isolation pattern DTI2 as in the embodiment shown in FIG. 10.

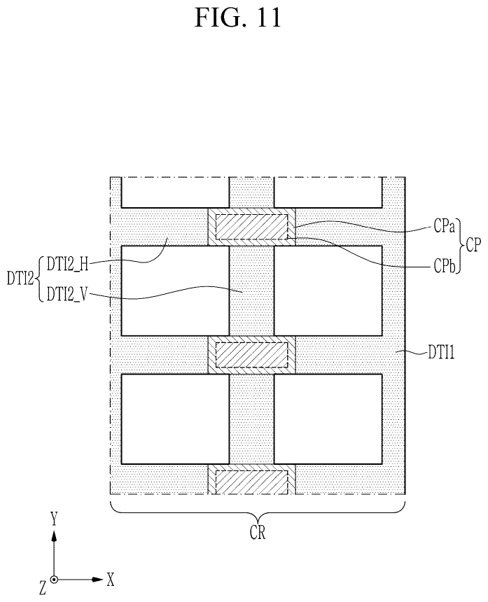

According to the embodiment shown in FIG. 11, the width of each of the plurality of dummy isolation contacts CP may be different from the width of a vertical isolation pattern portion DTI2_V of a dummy isolation pattern DTI2 and be substantially equal to the width of a horizontal isolation pattern portion DTI2_H, unlike in the embodiment shown in FIG. 5.

For example, the width of the first portion CPa of each of the dummy isolation contacts CP in the first direction X and the width of the second portion CPb in the first direction X may be greater than the width of the vertical isolation pattern portion DTI2_V in the first direction X.

The width of the first portion CPa of each of the dummy isolation contacts CP in the second direction Y and the width of a horizontal isolation pattern portion DTI2_H of a dummy isolation pattern DTI2 in the second direction Y may be substantially the same, and the width of the second portion CPb of each dummy isolation contact CP in the second direction Y may be smaller than the width of the vertical isolation pattern portion DTI2_V in the second direction Y.

In some embodiments, the width of the first portion CPa of each of the dummy isolation contacts CP in the first direction X may be substantially equal to the width of a vertical isolation pattern portion DTI2_V of a dummy isolation pattern DTI2 in the first direction X, and the width of the second portion CPb in the first direction X may be smaller than the width of the vertical isolation pattern portion DTI2_V in the first direction X.

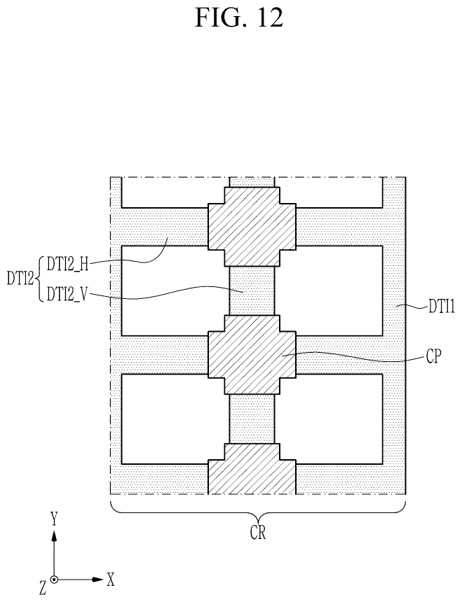

The embodiment shown in FIG. 12 is different from the embodiment shown in FIG. 5 in the planer shape.

For example, referring to FIG. 12, each of the plurality of dummy isolation contacts CP may be provided at an area where the horizontal isolation pattern portion DTI2_H and vertical isolation pattern portion DTI2_V of the dummy isolation pattern DTI2 intersect, and may have a cross shape on a plane.

Each of the plurality of dummy isolation contacts CP may be provided in an area where a horizontal isolation pattern portion DTI2_H and a vertical isolation pattern portion DTI2_V intersect, so as to extend in the first direction X and the second direction Y and overlap the horizontal isolation pattern portion DTI2_H and the vertical isolation pattern portion DTI2_V.

According to an example embodiment in FIG. 12, the widths of the plurality of dummy isolation contacts CP in the first direction X and the second direction Y are greater than the width of the vertical isolation pattern portion DTI2_V in first direction X and the width of the horizontal isolation pattern portion DTI2_H in the second direction Y, respectively. However, the disclosure is not limited thereto, and as such, the widths of the plurality of dummy isolation contacts CP in the first direction X and the second direction Y may be substantially equal to the width of the vertical isolation pattern portion DTI2_V in first direction X and the width of the horizontal isolation pattern portion DTI2_H in the second direction Y, respectively.

According to the image sensors of the embodiments shown in FIGS. 9 to 12, the arrangement and shape of the dummy isolation contact CP may be variously changed depending on the arrangements of components included in the image sensors and the sizes of pixels, whereby the image sensors may have substantially the same effects as those of the image sensor 10 according to the embodiment.

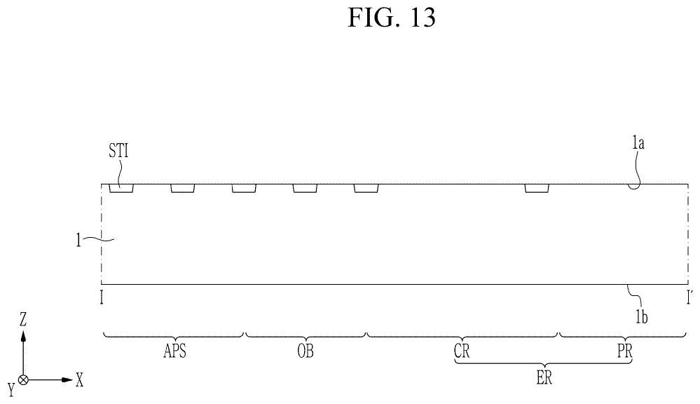

Hereinafter, a method of manufacturing an image sensor will be described with reference to FIGS. 13 to 24. Hereinafter, components identical to components described above will be denoted by the same reference symbols, and a redundant description thereof will not be made or will be made in brief, and the differences in them from the above-described components will be mainly described.

FIGS. 13 to 24 are cross-sectional views sequentially illustrating a method of manufacturing the image sensor according to an embodiment.

For example, FIGS. 13 to 24 are cross-sectional views corresponding to a cross-sectional view taken along line I-I′ of FIG. 5.

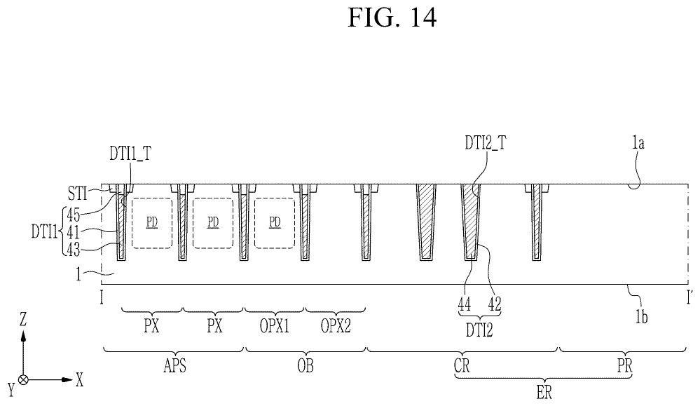

Referring to FIGS. 13 and 14, the first substrate 1 including the first surface 1a and the second surface 1b facing each other may be provided. The first substrate 1 may include the pixel area APS, the optical black area OB, the contact region CR, and the pad region PR. The contact region CR and the pad region PR may constitute the peripheral area ER.

The first substrate 1 may be, for example, a silicon single crystal wafer, a silicon epitaxial layer, or a silicon on insulator (SOI) substrate. The first substrate 1 may be doped with an impurity of the first conductivity type by performing an ion implantation process or the like on the first substrate 1. For example, the impurity of the first conductivity type may be a p-type impurity.

According to an embodiment, the element isolation pattern STI may be formed on the first surface 1a of the first substrate 1. The element isolation pattern STI may be formed in the pixel area APS, optical black area OB, and contact region CR of the first substrate 1. For example, a region in the contact region CR where the element isolation pattern STI is formed may be an area where the dummy isolation pattern DTI2 will be formed in a subsequent process.

The element isolation pattern STI may define the active areas (reference symbol “ACT” in FIG. 5). The element isolation pattern STI may be formed by a shallow trench isolation (STI) process.

The operation of forming the element isolation pattern STI may include an operation of forming a mask pattern on the first surface 1a of the first substrate 1 and forming a trench in the first surface 1a of the first substrate 1 using the mask pattern as an etch mask, and an operation of filling the trench with an insulating material and performing a planarizing process using chemical mechanical polishing (CMP), etch back, or the like.

According to an embodiment, by etching some portions of the first substrate 1, the first isolation trench DTI1_T may be formed from the first surface 1a of the first substrate 1 toward the second surface 1b so as to pass through the element isolation pattern STI in the pixel area APS, the optical black area OB, and the contact region CR, and the second isolation trench DTI2_T may be formed in the contact region CR from the first surface 1a of the first substrate 1 toward the second surface 1b.

The first isolation trench DTI1_T may define the area where the pixel isolation pattern DTI1 is formed, and the second isolation trench DTI2_T may define the area where the dummy isolation pattern DTI2 is formed.

The widths of the first isolation trench DTI1_T and the second isolation trench DTI2_T may decrease in a direction from the first surface 1a of the first substrate 1 toward the second surface 1b. For example, each of the first isolation trench DTI1_T and the second isolation trench DTI2_T may have a maximum width at the first surface 1a of the first substrate 1, and each of the first isolation trench DTI1_T and the second isolation trench DTI2_T may have a minimum width at the bottom surface.

The width of the first isolation trench DTI1_T may be smaller than the width of the second isolation trench DTI2_T. For example, the maximum width and minimum width of the second isolation trench DTI2_T may be greater than the maximum width and minimum width of the first isolation trench DTI1_T, respectively.

According to an embodiment, an insulating material layer for forming the first insulating isolation pattern 41 and the second insulating isolation pattern 42 may be formed so as to conform to the first surface 1a of the first substrate 1, the inner side surface and bottom surface of the first isolation trench DTI1_T, and the inner side surface and bottom surface of the second isolation trench DTI2_T.

According to an embodiment, the first conductive isolation pattern 43 and the second conductive isolation pattern 44 may be formed inside the first isolation trench DTI1_T and the second isolation trench DTI2_T, respectively, by filling each of the first isolation trench DTI1_T and the second isolation trench DTI2_T with a conductive material and performing an etch back process.

As the second isolation trench DTI2_T is formed wider than the width of the first isolation trench DTI1_T as described above, the maximum width and minimum width of the first conductive isolation pattern 43 formed inside the first isolation trench DTI1_T may be smaller than the maximum width and minimum width of the second conductive isolation pattern 44 formed inside the second isolation trench DTI2_T, respectively.

According to an embodiment, the first insulating isolation pattern 41 and the second insulating isolation pattern 42 may be formed inside the first isolation trench DTI1_T and the second isolation trench DTI2_T by forming the isolation capping pattern 45 on the first conductive isolation pattern 43 provided inside the first isolation trench DTI1_T and removing some portions of the insulating material layer, which is for forming the first insulating isolation pattern 41 and the second insulating isolation pattern 42, provided on the first surface 1a of the first substrate 1.

In this way, the pixel isolation pattern DTI1 including the first insulating isolation pattern 41, the first conductive isolation pattern 43, and the isolation capping pattern 45 and the dummy isolation pattern DTI2 including the second insulating isolation pattern 42 and the second conductive isolation pattern 44 may be formed.

The pixel isolation pattern DTI1 may define the active pixels PX and the black pixels OPX1 and OPX2 in the pixel area APS and the optical black area OB, respectively.

According to an embodiment, the photoelectric converters PD may be formed by performing an ion implantation process or the like on the pixel area APS and the optical black area OB of the first substrate 1. The photoelectric converters PD may be doped with an impurity of the second conductivity type. For example, the impurity of the second conductivity type may be an n-type impurity.

The photoelectric converters PD may be formed so as to correspond to the active pixels PX in the pixel area APS, respectively. The photoelectric converters PD may be formed in the area corresponding to the first black pixel OPX1 and may not be formed in the area corresponding to the second black pixel OPX2, in the optical black area OB.

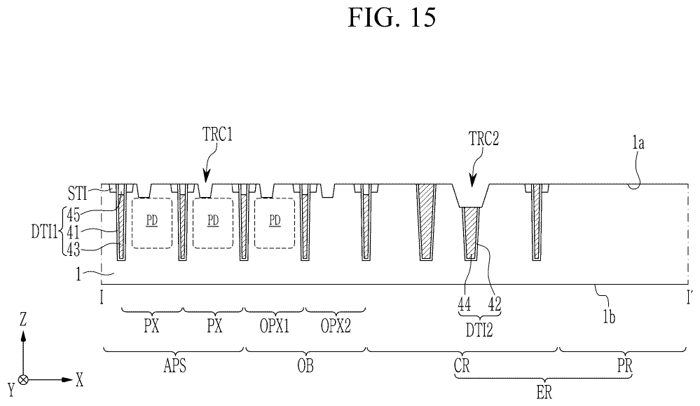

According to an embodiment, referring to FIG. 15, a first trench TRC1 may be formed in the pixel area APS and the optical black area OB by etching a portion of the first substrate 1, and a second trench TRC2 may be formed in the contact region CR by etching some portions of the first substrate 1 and the dummy isolation pattern DTI2.

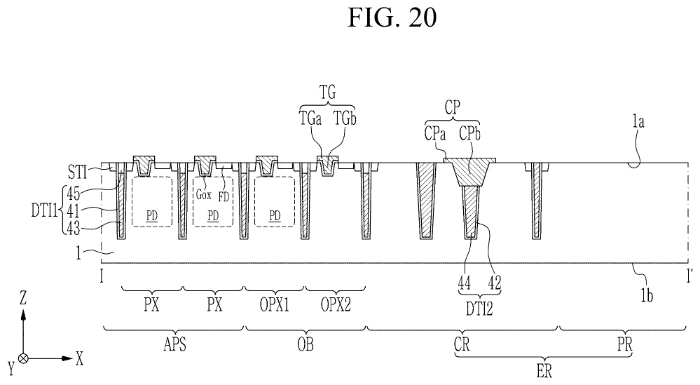

The first trench TRC1 may define an area where a transfer gate (reference symbol “TG” in FIG. 20) will be formed in a subsequent process, and the second trench TRC2 may define an area where a dummy isolation contact (reference symbol “CP” in FIG. 20) will be formed in a subsequent process.

The widths of the first trench TRC1 and the second trench TRC2 may decrease from the first surface 1a of the first substrate 1 toward the second surface 1b. For example, each of the first trench TRC1 and the second trench TRC2 may have a maximum width at the first surface 1a of the first substrate 1, and each of the first trench TRC1 and the second trench TRC2 may have a minimum width at the bottom surface.

The width of the first trench TRC1 may be smaller than the width of the second trench TRC2. For example, the maximum width and minimum width of the second trench TRC2 may be greater than the maximum width and minimum width of the first trench TRC1, respectively.

The depth of the second trench TRC2 may be deeper than the depth of the first trench TRC1. For example, the bottom surface of the second trench TRC2 may be provided at a level lower than the bottom surface of the first trench TRC1. For example, the bottom surface of the second trench TRC2 may be provided closer to the second surface 1b of the first substrate 1 than the bottom surface of the first trench TRC1.

The second trench TRC2 may expose the dummy isolation pattern DTI2 in the contact region CR. The maximum width of the dummy isolation pattern DTI2 exposed by the second trench TRC2 may be smaller than the minimum width of the second trench TRC2.

Accordingly, some portions of the first substrate 1 and the dummy isolation pattern DTI2 may be exposed by the second trench TRC2, and the first substrate 1 and the exposed dummy isolation pattern DTI2 may constitute the bottom surface of the second trench TRC2.

Further, as the second trench TRC2 is formed by etching a portion of the dummy isolation pattern DTI2, the length of the dummy isolation pattern DTI2 exposed by the second trench TRC2 may be shorter than the length of the dummy isolation pattern DTI2 unexposed by the second trench TRC2.

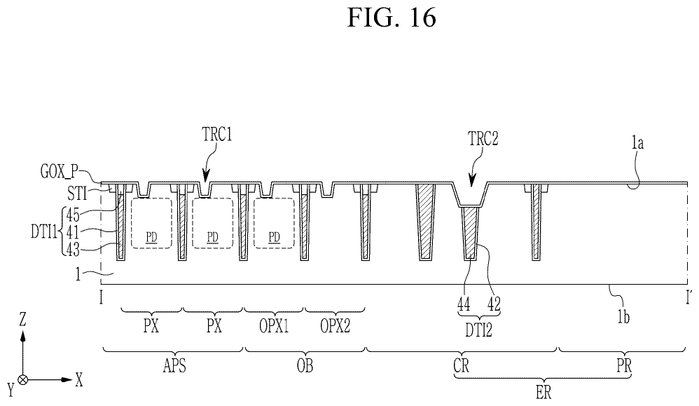

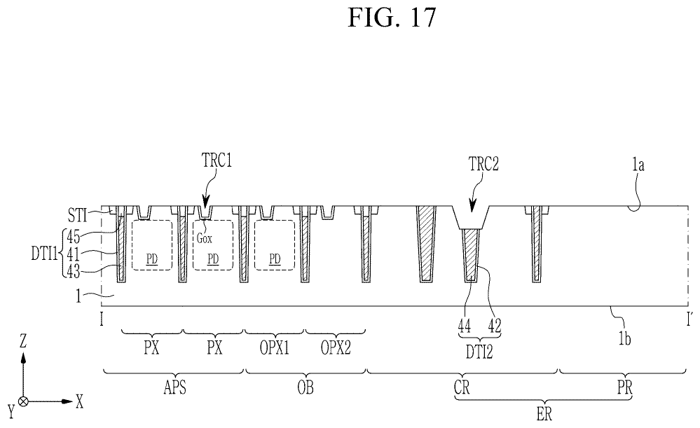

According to an embodiment, referring to FIGS. 16 and 17, a gate dielectric material layer GOX_P may be formed on the entire first surface 1a of the first substrate 1.

The gate dielectric material layer GOX_P may be formed so as to conform to the first surface 1a of the first substrate 1, the inner side surface and bottom surface of the first trench TRC1, and the inner side surface and bottom surface of the second trench TRC2. The gate dielectric material layer GOX_P may expose one surface of the dummy isolation pattern DTI2 exposed by the second trench TRC2.

The gate dielectric material layer GOX_P may contain an insulating material such as silicon oxide.

According to an embodiment, the gate dielectric material layer GOX_P formed on the first surface 1a of the first substrate 1 and the inner side surfaces and bottom surface of the second trench TRC2 may be removed by performing patterning on the gate dielectric material layer GOX_P.

Accordingly, the gate dielectric layer Gox may be formed on the inner side surfaces and bottom surface of the first trench TRC1 so as to conform to them.

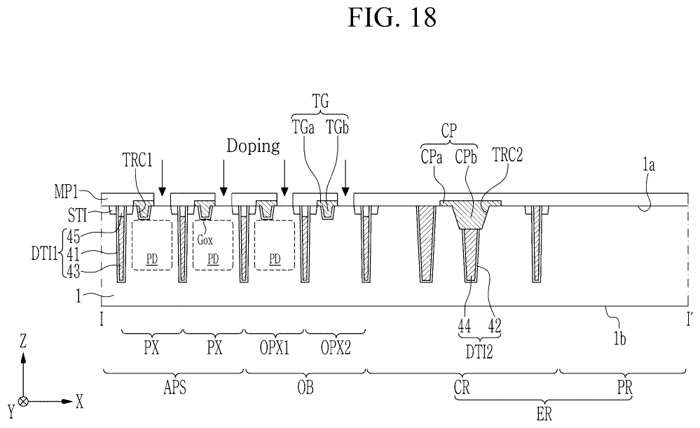

According to an embodiment, referring to FIG. 18, the transfer gate TG and the dummy isolation contact CP may be formed simultaneously.

For example, the operation of simultaneously forming the transfer gate TG and the dummy isolation contact CP may include forming a conductive material layer on the first surface 1a of the first substrate 1, the first trench TRC1 and the second trench TRC2, and performing patterning on the conductive material layer. For example, the conductive material layer may be provided or formed to cover the first surface 1a of the first substrate 1 and fill the first trench TRC1 and the second trench TRC2.

As the transfer gate TG and the dummy isolation contact CP are simultaneously formed by performing patterning on the conductive material layer, they may contain the same material. The conductive material layer may be, for example, polycrystalline silicon.

The first portion TGa of the transfer gate TG may be formed on the first surface 1a of the first substrate 1, and the second portion TGb may be formed inside the first substrate 1. For example, the second portion TGb of the transfer gate TG may be formed on the gate dielectric layer Gox inside the first trench TRC1, and the first portion TGa may be formed on the second portion TGb of the transfer gate TG and the first surface 1a of the first substrate 1 adjacent to the first trench TRC1.

The first portion CPa of the dummy isolation contact CP may be formed on the first surface 1a of the first substrate 1, and the second portion CPb may be formed inside the first substrate 1. For example, the second portion CPb of the dummy isolation contact CP may be formed on the dummy isolation pattern DTI2 inside the second trench TRC2, and the first portion CPa may be formed on the second portion CPb of the dummy isolation contact CP and the first surface 1a of the first substrate 1 adjacent to the second trench TRC2.

According to an embodiment, a first mask pattern MP1 may be formed on the first surface 1a of the first substrate 1. The first mask pattern MP1 may expose a partial area of the first substrate 1 provided between the transfer gate TG and the element isolation pattern STI.

The first mask pattern MP1 may be provided on the first surface 1a of the first substrate 1, the transfer gate TG, the dummy isolation contact CP, the element isolation pattern STI, the pixel isolation pattern DTI1, and the dummy isolation pattern DTI2. For example, the first mask pattern MP1 may cover the first surface 1a of the first substrate 1, the transfer gate TG, the dummy isolation contact CP, the element isolation pattern STI, the pixel isolation pattern DTI1, and the dummy isolation pattern DTI2.

In the example embodiment in FIG. 18, the first mask pattern MP1 entirely covers the first portion TGa of the transfer gate TG. However, the disclosure is not limited thereto, and as such, according to another embodiment, the first mask pattern MP1 may be provided on the first portion TGa of the transfer gate TG. For example, the first mask pattern MP1 may cover a portion of the first portion TGa of the transfer gate TG. In an example case in which the first mask pattern MP1 covers a portion of the first portion TGa of the transfer gate TG as mentioned above, the first portion TGa of the transfer gate TG may serve as a mask in a doping operation for forming the floating diffusion zone FD to be described below.

According to an embodiment, an ion implantation process may be performed using the first mask pattern MP1. The floating diffusion zone FD may be formed by doping an area adjacent to the first surface 1a of the first substrate 1 exposed by the first mask pattern MP1 with an impurity of the second conductivity type. For example, the impurity of the second conductivity type may be an n-type impurity.

The floating diffusion zone FD may be formed on one side of the transfer gate TG. For example, the floating diffusion zone FD may be formed between the transfer gate TG and the element isolation pattern STI. Since the dummy isolation contact CP is covered by the first mask pattern MP1, the dummy isolation contact CP may not be doped with the impurity of the second conductivity type.

In the operation performing doping with the impurity of the second conductivity type, source/drain regions adjacent to the transfer gate (reference symbol “TG” in FIG. 5), the source follower gate (reference symbol “SF” in FIG. 5), the reset gate (reference symbol “RG” in FIG. 5), and the selection gate (reference symbol “SEL” in FIG. 5) may be formed together.

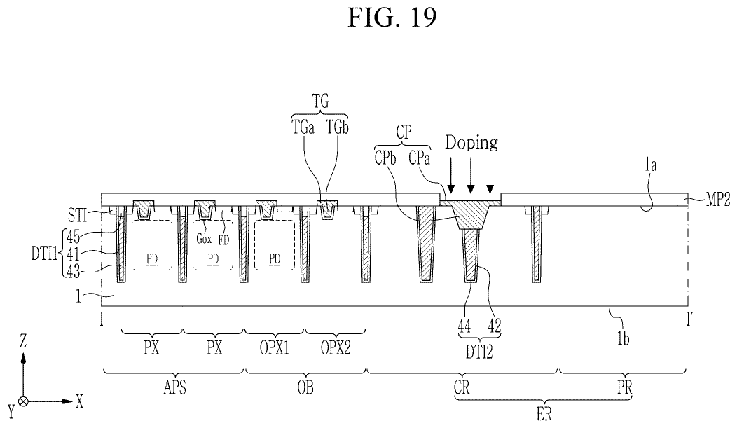

According to an embodiment, referring to FIGS. 19 and 20, after the first mask pattern MP1 is removed, a second mask pattern MP2 may be formed on the first surface 1a of the first substrate 1 so as to expose the dummy isolation contact CP.

The second mask pattern MP2 may expose the first portion CPa of the dummy isolation contact CP. The second mask pattern MP2 may be provided on the first surface 1a of the first substrate 1, the transfer gate TG, the dummy isolation contact CP, the element isolation pattern STI, the pixel isolation pattern DTI1, and the dummy isolation pattern DTI2. For example, the second mask pattern MP2 may cover the first surface 1a of the first substrate 1, the transfer gate TG, the dummy isolation contact CP, the element isolation pattern STI, the pixel isolation pattern DTI1, and the dummy isolation pattern DTI2.

According to an embodiment, an ion implantation process may be performed using the second mask pattern MP2 as a mask. The dummy isolation contact CP exposed by the second mask pattern MP2 may be doped with an impurity of the first conductivity type. For example, the impurity of the first conductivity type may be a p-type impurity.

Accordingly, at least a portion of the dummy isolation contact CP may be doped with the impurity of the first conductivity type. For example, the first portion CPa and second portion CPb of the dummy isolation contact CP may be doped with the impurity of the first conductivity type.

According to an embodiment, the second mask pattern MP2 may be removed such as the first surface 1a of the first substrate 1 is exposed. Further, as the second mask pattern MP2 is removed, the first portion TGa of the transfer gate TG, the floating diffusion zone FD, and the first portion CPa of the dummy isolation contact CP may be exposed.

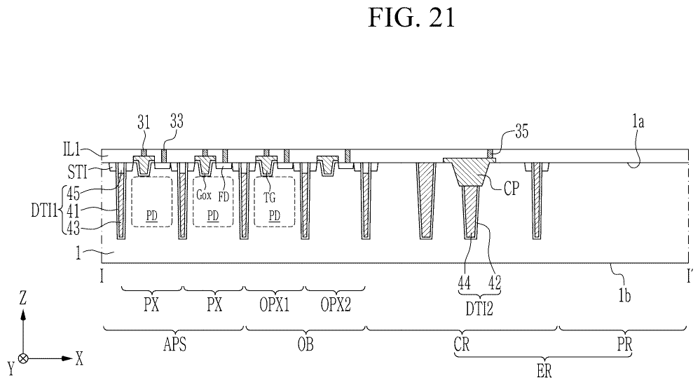

According to an embodiment, referring to FIG. 21, the first upper interlayer insulating layer IL1 may be formed on the first surface 1a of the first substrate 1 so as to cover the transfer gate TG and the dummy isolation contact CP.

According to an embodiment, the first upper contact plug 31 that passes through the first upper interlayer insulating layer IL1 and is connected to the transfer gate TG, the second upper contact plug 33 that passes through the first upper interlayer insulating layer IL1 and is connected to the floating diffusion zone FD, and the third upper contact plug 35 that passes through the first upper interlayer insulating layer IL1 and is connected to the dummy isolation contact CP may be formed.

The first to third upper contact plugs 31, 33, and 35 may be formed simultaneously or sequentially. The process operation of forming the first to third upper contact plugs 31, 33, and 35 may include an operation of forming holes through the first upper interlayer insulating layer IL1 so as to expose the transfer gate TG, the floating diffusion zone FD, and the dummy isolation contact CP, respectively, and filling the holes with a conductive material, and performing a planarizing process.

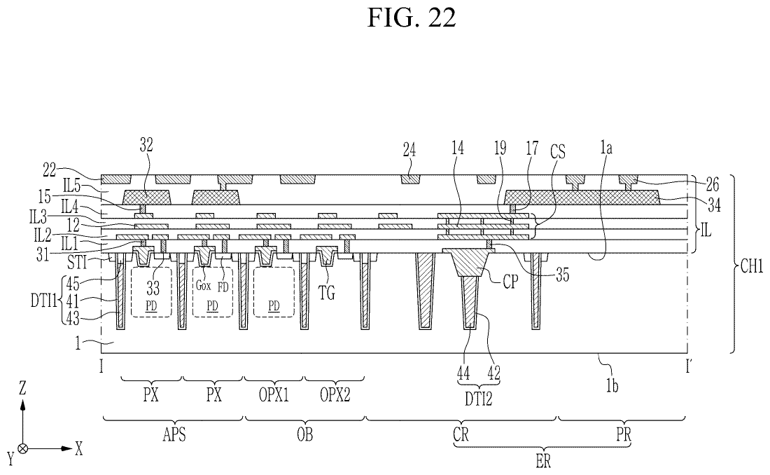

According to an embodiment, referring to FIG. 22, the first wiring lines 12 may be formed in the second to fourth upper interlayer insulating layers IL2, IL3, and IL4 on the first upper interlayer insulating layer IL1 and between or inside the first to fourth upper interlayer insulating layers IL1, IL2, IL3, and IL4. The first wiring lines 12 may contain a conductive material such as copper (Cu).

In the operation of forming the first wiring lines 12, the connection wiring lines 14 and the intermediate contacts 19 for connecting the connection wiring lines 14 may be formed in the contact region CR of the first substrate 1.

The connection wiring lines 14 and the intermediate contacts 19 may be formed together with the first wiring lines 12 by the same process, and contain the same material. The connection wiring lines 14 and the intermediate contacts 19 may constitute a connection wiring structure CS.

According to an embodiment, a first lower contact plug 15 and a second lower contact plug 17 may be formed. For example, the first lower contact plug 15 and the second lower contact plug 17 may be formed through a damascene process. For example, the first lower contact plug 15 may be configured to pass through the fourth upper interlayer insulating layer IL4 and connect to a first wiring line 12, and the second lower contact plug 17 may be configured to pass passes through the fourth upper interlayer insulating layer IL4 and connect to a connection wiring line 14.

The first lower contact plug 15 and the second lower contact plug 17 may contain a conductive material different from that of the first wiring lines 12. For example, the first lower contact plug 15 and the second lower contact plug 17 may contain a conductive material such as tungsten.

The operation of forming the first lower contact plug 15 and the second lower contact plug 17 may include an operation of forming holes in the fourth upper interlayer insulating layer IL4 so as to expose a first wiring line 12 and a connection wiring line 14, respectively, and filling the holes with a conductive material layer, and performing a planarizing process.

According to an embodiment, the fifth upper interlayer insulating layer IL5 may be formed, and the first metal pad 32 that is connected to the first lower contact plug 15 and the second metal pad 34 that is connected to the second lower contact plug 17 may be formed inside the fifth upper interlayer insulating layer IL5. The first metal pad 32 may be formed in the pixel area APS, and the second metal pad 34 may be formed in the peripheral area ER.

The first metal pad 32 and the second metal pad 34 may contain a conductive material such as aluminum (AI).

The first to fifth upper interlayer insulating layers IL1, IL2, IL3, IL4, and IL5 may constitute the upper interlayer insulating layer IL.

According to an embodiment, the first upper connection pad 22, the second upper connection pad 24, and the third upper connection pad 26 may be formed inside the fifth upper interlayer insulating layer IL5 by performing a damascene process.

The first upper connection pad 22 may pass through the fifth upper interlayer insulating layer IL5 and be connected to the first metal pad 32, and the third upper connection pad 26 may pass through the fifth upper interlayer insulating layer IL5 and be connected to the second metal pad 34.

The operation of forming the first upper connection pad 22, the second upper connection pad 24, and the third upper connection pad 26 may include an operation of filling a conductive material layer in holes passing through the fifth upper interlayer insulating layer IL5 and exposing the first metal pad 32 and the second metal pad 34 and performing a planarizing process.

The first upper connection pad 22, the second upper connection pad 24, and the third upper connection pad 26 may contain a conductive material such as copper (Cu).

According to some embodiments, the manufacturing process may include an operation of forming an upper bonding insulating layer on the fifth upper interlayer insulating layer IL5. For example, the upper bonding insulating layer may contain at least one of SiCN, SiOCN, and SiC.

The first chip CH1 may be formed by the operations described above with reference to FIGS. 13 to 22.

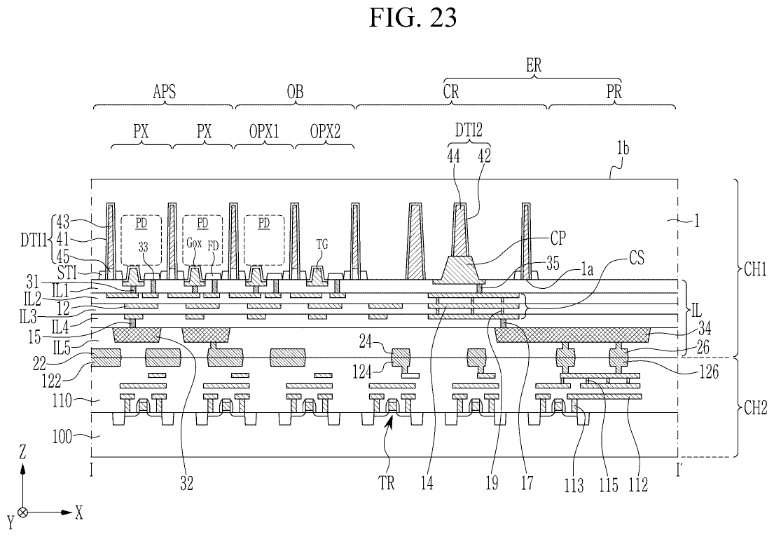

According to an embodiment, referring further to FIG. 23 together with FIG. 22, the first chip CH1 may be bonded onto the second chip CH2 having the structure described above with reference to FIG. 6.

For example, the first chip CH1 shown in FIG. 22 may be flipped over such that one surface of the upper interlayer insulating layer IL of the first chip CH1 comes into contact with one surface of the lower interlayer insulating layer 110 of the second chip CH2.

Therefore, the first upper connection pad 22, the second upper connection pad 24, and the third upper connection pad 26 provided inside the fifth upper interlayer insulating layer IL5 of the first chip CH1 may be in direct contact with the first lower connection pad 122, the second lower connection pad 124, and the third lower connection pad 126 of the second chip CH2, respectively.

The operation of bonding the first chip CH1 and the second chip CH2 may include an operation of providing the chips such that the upper connection pads 22, 24, and 26 and the lower connection pads 122, 124, and 126 are in contact with each other and performing a thermal compression process.

According to some embodiments, the second chip CH2 may further include the lower bonding insulating layer on the lower interlayer insulating layer 110, and the lower bonding insulating layer may be in contact with the above-mentioned upper bonding insulating layer and contain the same material as that of the upper bonding insulating layer, and the upper bonding insulating layer and the lower bonding insulating layer may be in contact with each other and be bonded.

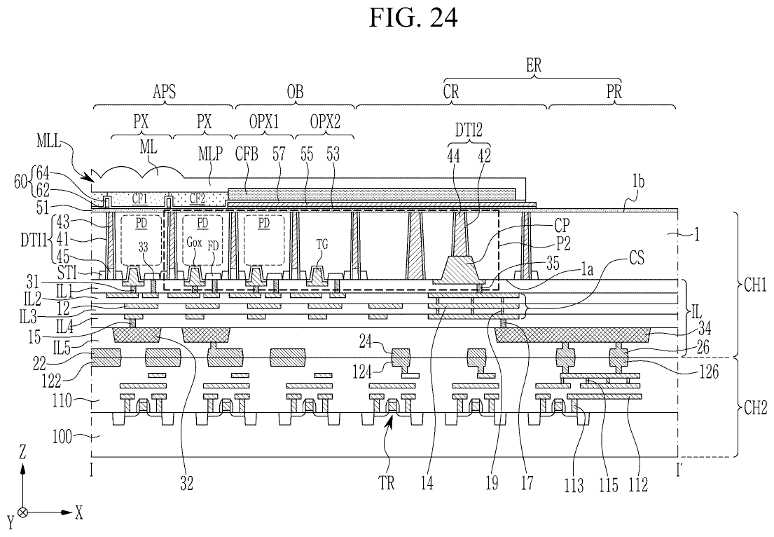

According to an embodiment, referring further to FIG. 24, as a grinding process is performed on the second surface 1b of the first substrate 1 shown in FIG. 23, some portions of the first substrate 1 may be etched, whereby the thickness of the first substrate 1 may be reduced.

In the operation of performing the grinding process on the second surface 1b of the first substrate 1, some portions of the ends of the pixel isolation pattern DTI1 and the dummy isolation pattern DTI2 may be removed together. Therefore, the end of the pixel isolation pattern DTI1 and the end of the dummy isolation pattern DTI2 may be aligned with substantially the same boundary, i.e., the second surface 1b of the first substrate 1.

According to an embodiment, the backside insulating layer 51 may be formed on the second surface 1b of the first substrate 1.

According to an embodiment, in the pixel area APS, the first grid pattern 62 and the second grid pattern 64 which contain different materials may be formed on the backside insulating layer 51, and in the optical black area OB and the contact region CR, the diffusion prevention pattern 53 and the first optical black pattern 55 may be formed on the backside insulating layer 51. However, the areas where the diffusion prevention pattern 53 and the first optical black pattern 55 are formed are not limited thereto, and may be variously changed. For example, the diffusion prevention pattern 53 and the first optical black pattern 55 may be formed so as to extend to the pad region PR.

The first grid pattern 62 and the second grid pattern 64 may constitute the grid pattern 60. The first grid pattern 62 and the diffusion prevention pattern 53 may be formed by the same process and contain the same material.

The grid pattern 60 may be formed so as to be shifted from the center of the photoelectric converters PD. For example, the grid pattern 60 may be formed so as to overlap some portions of the pixel isolation patterns DTI1 or may be formed so as not to overlap the pixel isolation patterns DTI1.

According to an embodiment, the passivation layer 57 may be formed on the second surface 1b of the first substrate 1. For example, the passivation layer 57 is formed to conform to the second surface 1b of the first substrate 1. The passivation layer 57 may be provided on the backside insulating layer 51, the grid pattern 60, the diffusion prevention pattern 53, and the first optical black pattern 5. For example, the passivation layer 57 may entirely cover the backside insulating layer 51, the grid pattern 60, the diffusion prevention pattern 53, and the first optical black pattern 55.

According to an embodiment, in the pixel area APS, the color filters CF1 and CF2 may be formed on the passivation layer 57, and in the optical black area OB and the contact region CR, the second optical black pattern CFB may be formed on the passivation layer 57.

The second optical black pattern CFB may be formed together with the blue color filter by the same process. For example, the second optical black pattern CFB may be formed together with the blue color filter by the same process.

The color filters CF1 and CF2 may be formed between the grid pattern 60 in the pixel area APS, and the color filters CF1 and CF2 may be formed so as to be shifted from the center of the photoelectric converters PD.

According to an embodiment, the micro lens layer MLL may be formed on the color filters CF1 and CF2 and the second optical black pattern CFB. The micro lens ML of the micro lens layer MLL may be formed on the color filters CF1 and CF2 in the pixel area APS, and the flat portion MLP may be formed in the pixel area APS, the optical black area OB, and the contact region CR. However, the areas where the flat portion MLP of the micro lens layer MLL is formed are not limited thereto, and may be variously changed. For example, the flat portion MLP of the micro lens layer MLL may be formed so as to extend to the pad region PR.

The micro lenses ML may be formed so as to be shifted from the centers of the photoelectric converters PD. Also, a micro lens ML may be formed so as to be relatively further shifted from the center of a photoelectric converter PD toward the first direction X as compared to the color filters CF1 and CF2.

According to an embodiment, referring to FIG. 6 together with FIG. 24, in the pad region PR, the exposure opening OR for exposing the second metal pad 34 may be formed, whereby the image sensor according to the embodiment shown in FIG. 6 may be completed.

The operation of forming the exposure opening OR may include an operation of forming a mask pattern and etching the first substrate 1 and the upper interlayer insulating layer IL using the mask pattern as an etch mask.

According to the method of manufacturing the image sensor according to the embodiment, as the dummy isolation contact CP which is connected to the dummy isolation pattern DTI2 is formed together in the operation of forming the transfer gate TG, some operations may be omitted and the manufacturing process may be simplified.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. An image sensor comprising:
a substrate comprising a pixel area comprising a plurality of pixels and a peripheral area provided outside the pixel area;
a plurality of photoelectric converters provided in the substrate corresponding to the plurality of pixels;
a pixel isolation pattern provided between the plurality of photoelectric converters;
a dummy isolation pattern provided inside the substrate in the peripheral area, the dummy isolation pattern having a width different from a width of the pixel isolation pattern; and
a dummy isolation contact provided on a first surface of the substrate in the peripheral area and connected to the dummy isolation pattern,
wherein a first portion of the dummy isolation contact is provided inside the substrate, and a width of the dummy isolation contact is greater than or substantially equal to the width of the dummy isolation pattern.

2. The image sensor of claim 1, wherein the dummy isolation contact comprises:
a second portion provided on the first surface of the substrate and the first portion that extends from the second portion into the substrate,
wherein a width of the second portion is greater than a width of the first portion.

3. The image sensor of claim 2, wherein:
the second portion of the dummy isolation contact extends in a direction parallel to the first surface of the substrate and has a flat shape, and
a width of the first portion of the dummy isolation contact decreases in a direction from the first surface of the substrate toward a second surface of the substrate opposite to the first surface of the substrate.

4. The image sensor of claim 2, wherein:
the dummy isolation pattern comprises a first surface facing the dummy isolation contact and a second surface opposite to the first surface of the dummy isolation pattern, and
a minimum width of the first portion of the dummy isolation contact is greater than a width of the first surface of the dummy isolation pattern.

5. The image sensor of claim 4, wherein:
the dummy isolation pattern comprises a conductive isolation pattern and an insulating isolation pattern provided on a side surface of the conductive isolation pattern, and
the dummy isolation contact is in direct contact with the conductive isolation pattern.

6. The image sensor of claim 5, wherein each of the conductive isolation pattern and the dummy isolation contact comprises polycrystalline silicon or doped polycrystalline silicon.

7. The image sensor of claim 6, wherein the dummy isolation contact is doped with a p-type impurity.

8. The image sensor of claim 2, further comprising:
a transfer gate provided on the first surface of the substrate in the pixel area,
wherein the transfer gate comprises:
a first portion provided on the first surface of the substrate, and
a second portion that extends from the first portion into the substrate, and
wherein a width of the first portion of the transfer gate is smaller than a width of the first portion of the dummy isolation contact, and
wherein a width of the second portion of the transfer gate is smaller than the width of the second portion of the dummy isolation contact.

9. The image sensor of claim 8, wherein an end of the second portion of the transfer gate is provided at a level different from that of an end of the second portion of the dummy isolation contact.

10. The image sensor of claim 9, wherein:
a thickness of the first portion of the transfer gate is substantially equal to a thickness of the first portion of the dummy isolation contact, and
a thickness of the second portion of the transfer gate is smaller than a thickness of the second portion of the dummy isolation contact.

11. The image sensor of claim 8, wherein:
the transfer gate and the dummy isolation contact comprise a same material.

12. The image sensor of claim 1, wherein:
a width of each of the pixel isolation pattern and the dummy isolation pattern decreases in a direction from the first surface of the substrate toward a second surface of the substrate, and
a maximum width of the dummy isolation pattern is greater than a maximum width of the pixel isolation pattern.

13. The image sensor of claim 12, wherein the maximum width of the dummy isolation pattern is substantially equal to or smaller than twice the maximum width of the pixel isolation pattern.

14. The image sensor of claim 1, wherein:
the peripheral area comprises a contact region, and an optical black area provided between the pixel area and the contact region,
the optical black area comprises at least one black pixel, and
the dummy isolation pattern and the dummy isolation contact are provided in the contact region.

15. An image sensor comprising:
a substrate comprising a pixel area comprising a plurality of pixels and a peripheral area provided outside the pixel area;
a plurality of photoelectric converters provided in the substrate corresponding to the plurality of pixels;
a pixel isolation pattern provided between the plurality of photoelectric converters;
a dummy isolation pattern provided inside the substrate in the peripheral area, the dummy isolation pattern having a width greater than a width of the pixel isolation pattern; and
a dummy isolation contact extending from a first surface of the substrate into the substrate in the peripheral area and connected to the dummy isolation pattern,
wherein the dummy isolation pattern comprises a horizontal isolation pattern portion that extends in a first direction parallel to the first surface the substrate, and a vertical isolation pattern portion that extends in a second direction intersecting the first direction,
wherein the dummy isolation contact is provided to overlap at least one of the horizontal isolation pattern portion and the vertical isolation pattern portion of the dummy isolation pattern, and
wherein a width of the dummy isolation contact is greater than at least one of a width of the horizontal isolation pattern portion and a width of the vertical isolation pattern portion.

16. The image sensor of claim 15, wherein the dummy isolation contact is provided at an area where the horizontal isolation pattern portion and the vertical isolation pattern portion intersect each other.

17. The image sensor of claim 16, wherein:
the dummy isolation contact extends in a direction substantially same as that of each of the horizontal isolation pattern portion and the vertical isolation pattern portion, and
the dummy isolation contact has a cross shape.

18. The image sensor of claim 15, wherein the dummy isolation contact overlaps one of the horizontal isolation pattern portion and the vertical isolation pattern portion of the dummy isolation pattern.

19. The image sensor of claim 15, wherein:
the dummy isolation contact comprises a plurality of dummy isolation contacts, and
the plurality of dummy isolation contacts are spaced apart from each other.

20. An image sensor comprising:
a substrate comprising a pixel area comprising a plurality of pixels and a peripheral area provided outside the pixel area;
a plurality of photoelectric converters provided inside the substrate so as to correspond to the plurality of pixels;
a pixel isolation pattern provided between the plurality of photoelectric converters;
a dummy isolation pattern provided inside the substrate in the peripheral area, the dummy isolation pattern having a width greater than a width of the pixel isolation pattern;
a dummy isolation contact that is provided on a first surface of the substrate in the peripheral area; and
a micro lens layer provided on a second surface of the substrate,
wherein the dummy isolation contact comprises a first portion provided on the first surface of the substrate, and a second portion extending from the first portion into the substrate and connected to the dummy isolation pattern,
wherein the dummy isolation pattern comprises a horizontal isolation pattern portion extending in a first direction parallel to the first surface of the substrate, and a vertical isolation pattern portion extending in a second direction intersecting the first direction,
wherein the dummy isolation contact is provided to overlap at least one of the horizontal isolation pattern portion and the vertical isolation pattern portion of the dummy isolation pattern, and
wherein a width of the dummy isolation contact is greater than at least one of a width of the horizontal isolation pattern portion and a width of the vertical isolation pattern portion.
